(19) United States
(12) Patent Application Publication
(10) Pub. No.: US 2024/0395781 A1
(43) Pub. Date: Nov. 28, 2024

(54) SEMICONDUCTOR PACKAGE AND METHOD FOR MANUFACTURING THE SAME

(71) Applicant: Samsung Electronics Co., Ltd., Suwon-si (KR)

(72) Inventor: Chengtar Wu, Suwon-si (KR)

(21) Appl. No.: 18/407,893

(22) Filed: Jan. 9, 2024

(30) Foreign Application Priority Data
May 25, 2023 (KR) 10-2023-0067546

(51) Int. Cl. H01L 25/10; H01L 23/00; H01L 23/28; H01L 23/48; H01L 23/522; H10B 80/00

(52) U.S. Cl. CPC H01L 25/105; H01L 23/28; H01L 23/481; H01L 23/5226; H01L 24/16; H01L 24/32; H01L 24/73; H10B 80/00; H01L 2224/16145; H01L 2224/32225; H01L 2224/73204

(57) ABSTRACT

A semiconductor package according to an embodiment includes a first three-dimensional integrated circuit structure; and a second three-dimensional integrated circuit structure on the first three-dimensional integrated circuit structure, wherein the first three-dimensional integrated circuit structure includes a baseband die; and a memory die on the baseband die, the second three-dimensional integrated circuit structure includes a transceiver die; and a radio communication die on the transceiver die, and the radio communication die includes one or more metal patterns on an upper surface thereon.

### CROSS-REFERENCE TO RELATED APPLICATION

This application claims priority to and the benefit of Korean Patent Application No. 10-2023-0067546 filed in the Korean Intellectual Property Office on May 25, 2023, the entire contents of which are incorporated herein by reference.

### BACKGROUND OF THE INVENTION

### (a) Field of the Invention

The present invention relates to a semiconductor package and a manufacturing method thereof.

### (b) Description of the Related Art

Radio communication technology uses ultra-high frequency bands to transmit complex computational signals more quickly and accurately over long distances. An antenna in package (AiP) module is well known as a module mounted on a radio communication device using such an ultra-high frequency band. An antenna in package (AiP) is a device that packages an antenna together with a Radio Frequency Integrated Circuit (RFIC) chip to be modularized into a single unit.

However, a conventional antenna in package (AiP) has a structure in which an antenna is disposed on the upper surface of a modified semi additive process (m-SAP) substrate and the RFIC chip is disposed on the lower surface of the m-SAP substrate. Therefore, in the conventional antenna in package (AiP), the distance between the antenna and the RFIC chip is long, and a signal attenuation problem may occur in the process of transferring the received signal from the antenna to the RFIC chip.

In addition, since the antenna and a feeding line of the conventional antenna in package (AiP) are manufactured within the m-SAP substrate, the antenna and the feeding line may have a rough surface, and accordingly, a signal integrity of the signal transmitted on the surface may be deteriorated, and an efficiency of the antenna may be reduced.

In addition, since the conventional antenna in package (AiP) is configured to include only the antenna and the RFIC chip and does not include a baseband chip, in the process of transmitting the signal from the antenna in package (AiP) to the baseband chip, the signal may be attenuated.

Therefore, it is important to develop a new semiconductor package technology that can address the issues of the conventional antenna in package (AiP) technology.

### SUMMARY OF THE INVENTION

So as to integrate an antenna, a radio communication die, a transceiver die, and a baseband die, it is possible to provide an antenna in package (AiP) implemented as a first three-dimensional integrated circuit (3DIC) structure including the baseband die, and the memory die on the baseband die; and a second three-dimensional integrated circuit structure including the transceiver die, and the radio communication die on the transceiver die.

A semiconductor package according to an embodiment includes a first three-dimensional integrated circuit structure; and a second three-dimensional integrated circuit structure on the first three-dimensional integrated circuit structure, wherein the first three-dimensional integrated circuit structure includes a baseband die; and a memory die on the baseband die, the second three-dimensional integrated circuit structure includes a transceiver die; and a radio communication die on the transceiver die, and the radio communication die includes one or more metal patterns on an upper surface thereon.

The radio communication die may include a RF chip.

Each metal pattern of one or more metal patterns may include a PIFA antenna or a patch antenna.

The transceiver die may include a transmitter TX for generating a first radio frequency (RF) signal and transmitting the generated first radio frequency (RF) signal; and a receiver RX for receiving a second radio frequency (RF) signal and processing the received second radio frequency (RF) signal.

The first three-dimensional integrated circuit structure may include a first redistribution layer structure on the lower surface of the baseband die; and a second redistribution layer structure between the baseband die and the memory die.

The baseband die may include a plurality of first through silicon vias, and the plurality of first through silicon vias may electrically connect the memory die to the first redistribution layer structure.

The first three-dimensional integrated circuit structure may further include a plurality of first connection members for electrically connecting the second redistribution layer structure to the baseband die.

The first three-dimensional integrated circuit structure may further include a first insulating member surrounding the plurality of first connection members.

The second three-dimensional integrated circuit structure may include a third redistribution layer structure on the lower surface of the transceiver die; and a fourth redistribution layer structure between the transceiver die and the radio communication die

The transceiver die may include a plurality of second through silicon vias, and the plurality of second through silicon vias may electrically connect the radio communication die to the third redistribution layer structure.

The radio communication die may include a plurality of third through silicon vias, and the plurality of third through silicon vias may electrically connect one or more metal patterns to the fourth redistribution layer structure.

The plurality of third through silicon vias may include a feeding line.

The second three-dimensional integrated circuit structure may further include a plurality of second connection members electrically connecting the fourth redistribution layer structure to the transceiver die.

The second three-dimensional integrated circuit structure may further include a second insulating member surrounding the plurality of second connection members.

A semiconductor package according to an embodiment includes a first three-dimensional integrated circuit structure; and a second three-dimensional integrated circuit structure on the first three-dimensional integrated circuit structure, wherein the first three-dimensional integrated circuit structure includes a first redistribution layer structure; a baseband die on the first redistribution layer structure; a second redistribution layer structure on the baseband die; a memory die on the second redistribution layer structure; a plurality of conductive posts on the baseband die; and a first molding material disposed on the baseband die and molding the memory die, the second redistribution layer structure, and the plurality of conductive posts, and the second three-dimensional integrated circuit structure includes a third redistribution layer structure; a transceiver die on the third redistribution layer structure; a fourth redistribution layer structure on the transceiver die; a radio communication die on the fourth redistribution layer structure, the radio communication die includes one or more antenna on the upper surface thereof; a second molding material disposed on the transceiver die and molding the radio communication die and the fourth redistribution layer structure; and a plurality of connection members electrically connecting the third redistribution layer structure to the plurality of conductive posts.

An insulating member surrounding the plurality of connection members may be further included.

The second molding material may cover the side surface of the radio communication die, and un upper surface of the radio communication die may be exposed to un outside.

A manufacturing method of a semiconductor package according to an embodiment includes manufacturing a first three-dimensional integrated circuit structure and a second three-dimensional integrated circuit structure; and mounting the second three-dimensional integrated circuit structure on the first three-dimensional integrated circuit structure, wherein the manufacturing of the first three-dimensional integrated circuit structure includes forming a plurality of first through silicon vias on a first surface of a baseband die; and mounting a memory die on a second surface opposite to the first surface of the baseband die, the manufacturing of the second three-dimensional integrated circuit structure includes forming a plurality of second through silicon vias on a first surface of a transceiver die; and mounting a radio communication die on a second surface opposite to the first surface of the transceiver die, the radio communication die includes one or more metal patterns on an upper surface thereof.

The manufacturing of the first three-dimensional integrated circuit structure may further include molding the memory die with a molding material on the second surface of the baseband die after mounting the memory die on the second surface opposite to the first surface of the baseband die.

The manufacturing of the first three-dimensional integrated circuit structure may further include, after molding the memory die on the second surface of the baseband die with a molding material, forming a plurality of conductive posts on the second surface of the baseband die.

So as to integrate the antenna, the radio communication die, the transceiver die, and the baseband die, it is possible to provide the semiconductor package implemented with the first three-dimensional integrated circuit structure including the baseband die and the memory die on the baseband die; and the second three-dimensional integrated circuit structure including the transceiver die, and the radio communication die on the transceiver die.

As a result, the interconnection connection distance between the antenna, radio communication die, transceiver die, and baseband die may be shortened. In the process of transmitting the signal, it is possible to reduce a signal attenuation and improve a signal integrity, and problems such as a long range and a propagation distance that occur in ultra-high frequency bands (e.g., 5G mm-Wave frequency) may be overcome.

### BRIEF DESCRIPTION OF THE DRAWINGS

FIG. 1 is a cross-sectional view showing a semiconductor package including a first three-dimensional (3D) integrated circuit structure and a second 3D integrated circuit structure on the first 3D integrated circuit structure, wherein the first 3D integrated circuit structure includes a baseband die, and a memory die on the baseband die, and the second 3D integrated circuit structure includes a transceiver die, and a radio communication die on the transceiver die.

FIG. 2 is a cross-sectional view showing a step of forming a second redistribution layer structure on a memory die as one step among steps of a manufacturing method of a first 3D integrated circuit structure.

FIG. 3 is a cross-sectional view showing a step of forming a first interconnection structure on a second redistribution layer structure as one step among steps of a manufacturing method of a first 3D integrated circuit structure.

FIG. 4 is a cross-sectional view showing a step of forming a first through silicon vias TSV in a baseband die as one step among steps of a manufacturing method of a first 3D integrated circuit structure.

FIG. 5 is a cross-sectional view showing a step of forming a first redistribution layer structure on a baseband die as one step among steps of a manufacturing method of a first 3D integrated circuit structure.

FIG. 6 is a cross-sectional view showing a step of forming a first external connection structure on a first redistribution layer structure as one step among steps of a manufacturing method of a first 3D integrated circuit structure.

FIG. 7 is a cross-sectional view showing a step of bonding a first carrier under a first redistribution layer structure and a first external connection structure as one step among steps of a manufacturing method of a first 3D integrated circuit structure.

FIG. 8 is a cross-sectional view showing a step of grinding a back side of a baseband die as one step among steps of a manufacturing method of a first 3D integrated circuit structure.

FIG. 9 is a cross-sectional view showing a step of forming first upper connection pads on a back side of a baseband die as one step among steps of a manufacturing method of a first 3D integrated circuit structure.

FIG. 10 is a cross-sectional view showing a step of mounting a memory die on which a second redistribution layer structure is formed on a baseband die as one step among steps of a manufacturing method of a first 3D integrated circuit structure.

FIG. 11 is a cross-sectional view showing a step of forming an insulating member between a baseband die and a second redistribution layer structure as one step among steps of a manufacturing method of a first 3D integrated circuit structure.

FIG. 12 is a cross-sectional view showing a step of covering a memory die on which a second redistribution layer structure is formed with a first molding material on a baseband die as one step among steps of a manufacturing method of a first 3D integrated circuit structure.

FIG. 13 is a cross-sectional view showing a step of planarizing a first molding material as one step among steps of a manufacturing method of a first 3D integrated circuit structure.

FIG. 14 is a cross-sectional view showing a step of forming through holes in a first molding material to form conductive posts as one step among steps of a manufacturing method of a first 3D integrated circuit structure.

FIG. 15 is a cross-sectional view showing a step of forming conductive posts by filling through holes with a conductive material as one step among steps of a manufacturing method of a first 3D integrated circuit structure.

FIG. 16 is a cross-sectional view showing a steps of de-bonding a first carrier from a first redistribution layer structure and a first external connection structure as one step among steps of a manufacturing method of a first 3D integrated circuit structure.

FIG. 17 is a cross-sectional view showing a step of forming third through silicon vias TSV in a radio communication die as one step among steps of a manufacturing method of a second 3D integrated circuit structure.

FIG. 18 is a cross-sectional view showing a step of forming a fourth redistribution layer structure on a radio communication die as one step among steps of a manufacturing method of a second 3D integrated circuit structure.

FIG. 19 is a cross-sectional view showing a step of forming a second interconnection connection structure on a fourth redistribution layer structure as one step among steps of a manufacturing method of a second 3D integrated circuit structure.

FIG. 20 is a cross-sectional view showing a step of bonding a second carrier under a second interconnection connection structure and a fourth redistribution layer structure as one step among steps of a manufacturing method of a second 3D integrated circuit structure.

FIG. 21 is a cross-sectional view showing a step of grinding a back side of a radio communication die as one step among steps of a manufacturing method of a second 3D integrated circuit structure.

FIG. 22 is a cross-sectional view showing a step of attaching antennas on a back side of a radio communication die as one step among steps of a manufacturing method of a second 3D integrated circuit structure.

FIG. 23 is a cross-sectional view showing a step of de-bonding a second carrier from a second interconnection connection structure and a fourth redistribution layer structure as one step among steps of a manufacturing method of a second 3D integrated circuit structure.

FIG. 24 is a cross-sectional view showing a step of forming second through silicon vias TSV in a transceiver die as one step among steps of a manufacturing method of a second 3D integrated circuit structure.

FIG. 25 is a cross-sectional view showing a step of forming a third redistribution layer structure on a transceiver die as one step among steps of a manufacturing method of a second 3D integrated circuit structure.

FIG. 26 is a cross-sectional view showing a step of forming a second external connection structure on a third redistribution layer structure as one step among steps of a manufacturing method of a second 3D integrated circuit structure.

FIG. 27 is a cross-sectional view showing a step of bonding a third carrier under a third redistribution layer structure and a second external connection structure as one step among steps of a manufacturing method of a second 3D integrated circuit structure.

FIG. 28 is a cross-sectional view showing a step of grinding a back side of a transceiver die as one step among steps of a manufacturing method of a second 3D integrated circuit structure.

FIG. 29 is a cross-sectional view showing a step of forming second upper connection pads on a back side of a transceiver die as one step among steps of a manufacturing method of a second 3D integrated circuit structure.

FIG. 30 is a cross-sectional view showing a step of mounting a radio communication die on which a fourth redistribution layer structure is formed on a transceiver die as one step among steps of a manufacturing method of a second 3D integrated circuit structure.

FIG. 31 is a cross-sectional view showing a step of forming an insulating member between a transceiver die and a fourth redistribution layer structure as one step among steps of a manufacturing method of a second 3D integrated circuit structure.

FIG. 32 is a cross-sectional view showing a step of covering a radio communication die on which a fourth redistribution layer structure is formed with a second molding material on a transceiver die as one step among steps of a manufacturing method of a second 3D integrated circuit structure.

FIG. 33 is a cross-sectional view showing a step of planarizing a second molding material as one step among steps of a manufacturing method of a second 3D integrated circuit structure.

FIG. 34 is a cross-sectional view showing a step of de-bonding a third carrier from a third redistribution layer structure and a second external connection structure as one step among steps of a manufacturing method of a second 3D integrated circuit structure.

FIG. 35 is a cross-sectional view showing a step of aligning a second 3D integrated circuit structure on a first 3D integrated circuit structure for a bonding as one step of steps of a manufacturing method of a semiconductor package.

FIG. 36 is a cross-sectional view showing a step of bonding a second 3D integrated circuit structure to a first 3D integrated circuit structure as one step of steps of a manufacturing method of a semiconductor package.

### DETAILED DESCRIPTION OF THE EMBODIMENTS

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present invention is not limited to the illustrated sizes and thicknesses.

Throughout this specification and the claims that follow, when it is described that a part is “connected” to another part, the part may be “directly connected” to the other element or “connected” to the other part through a third part. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on, above, or below the object portion, and does not necessarily mean positioned on the upper side of the object portion based on a gravitational direction.

Further, in the specification, the phrase “on a plane” means when an object portion is viewed from above, and the phrase “on a cross-section” means when a cross-section taken by vertically cutting an object portion is viewed from the side.

Hereinafter, a semiconductor package 10 and a manufacturing method of the semiconductor package 10 according to an embodiment will be described with reference to drawings.

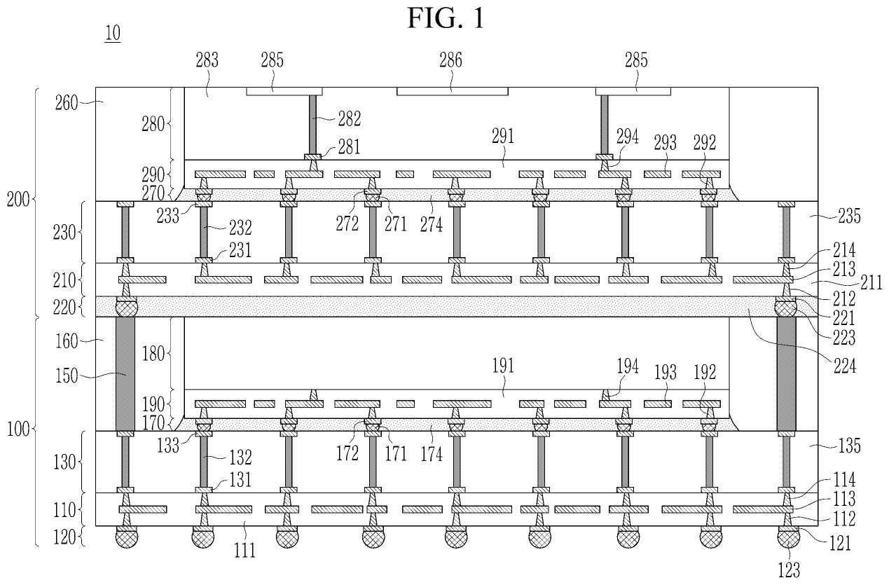

FIG. 1 is a cross-sectional view showing a semiconductor package 10 including a first three-dimensional (3D) integrated circuit structure 100 and a second 3D integrated circuit structure 200 on the first 3D integrated circuit structure 100, wherein the first 3D integrated circuit structure 100 includes a baseband die 130, and a memory die 180 on the baseband die 130, and the second 3D integrated circuit structure 200 includes a transceiver die 230, and a radio communication die 280 on the transceiver die 230.

Referring to FIG. 1, the semiconductor package 10 may include the first 3D integrated circuit structure 100 and the second 3D integrated circuit structure 200.

The first 3D integrated circuit structure 100 may include a first redistribution layer (RDL) structure 110, a baseband die 130, a first interconnection connection structure 170, a second redistribution layer structure 190, a memory die 180, conductive posts 150, a first molding material 160, and a first external connection structure 120.

The first redistribution layer structure 110 may include a first dielectric material layer 111, first redistribution layer vias 112, first redistribution layer lines 113, and second redistribution layer vias 114 formed in the first dielectric material layer 111. In another embodiment, the redistribution layer structure including fewer or more redistribution layer lines and redistribution layer vias is included in the scope of the present disclosure.

The first dielectric material layer 111 protects and insulates the first redistribution layer vias 112, the first redistribution layer lines 113, and the second redistribution layer vias 114. The baseband die 130 may be disposed on the upper surface of the first dielectric material layer 111, and the first external connection structure 120 may be disposed on the lower surface of the first dielectric material layer 111.

The first redistribution layer via 112 may be disposed between the first redistribution layer line 113 and the first conductive pad 121 of the first external connection structure 120. The first redistribution layer via 112 may electrically connect the first redistribution layer line 113 to the first conductive pad 121 in a vertical direction. The first redistribution layer line 113 may be disposed between the first redistribution layer via 112 and the second redistribution layer via 114. The first redistribution layer line 113 may electrically connect the first redistribution layer via 112 to the second redistribution layer via 114 in a horizontal direction. The second redistribution layer via 114 may be disposed between the first redistribution layer line 113 and the first lower connection pad 131 of the baseband die 130. The second redistribution layer via 114 may electrically connect the first lower connection pad 131 of the baseband die 130 to the first redistribution layer line 113 in a vertical direction. The second redistribution layer via 114 may be directly connected to the first lower connection pad 131 of the baseband die 130 without any other connection member. In an embodiment, the first redistribution layer via 112 and the second redistribution layer via 114 may have a width of the uppermost portion smaller than a width of the lowest portion.

The baseband die 130 may include first lower connection pads 131, first through silicon vias (TSV; 132), first upper connection pads 133, and a baseband chip 135.

The first lower connection pad 131 may be disposed between the first through silicon via (TSV; 132) and the second redistribution layer via 114. The first lower connection pad 131 may electrically connect the first through silicon via (TSV) 132 to the second redistribution layer via 114.

The first through silicon via (TSV) 132 may be disposed between the first lower connection pad 131 and the first upper connection pad 133. The first through silicon via (TSV) 132 may electrically connect the first upper connection pad 133 to the first lower connection pad 131. In the first 3D integrated circuit structure 100, since the memory die 180 is separated from a substrate that transmits thereto, and receives therefrom, a signal and a power, the first through silicon via (TSV) 132 is disposed within the baseband die 130 and electrically connected to the memory die 180, thereby increasing the speed of receiving and responding to the signal and power of the memory die 180.

The first upper connection pad 133 may be disposed between the first through silicon via (TSV) 132 and the first connection member 171. The first upper connection pad 133 may electrically connect the first connection member 171 to the first through silicon via (TSV) 132.

The baseband chip 135 transmits and receives baseband signals to/from the RFIC chip 283 (described later) and modulates the baseband. A conventional antenna in package (AiP) is only configured to include an antenna and an RFIC chip, but does not include a baseband chip, so the signal is attenuated in the process of transmitting the signal from the antenna in package (AiP) to the baseband chip. However, according to the present disclosure, the baseband chip 135 is on the baseband die 130 of the first 3D integrated circuit structure 100, and the RFIC chip 283 is disposed on the radio communication die 280 of the second 3D integrated circuit structure 200, thereby minimizing the distance between the RFIC chip 283 and the baseband chip 135 and reducing a signal attenuation.

The first interconnection connection structure 170 may be disposed between the baseband die 130 and the second redistribution layer structure 190. The first interconnection connection structure 170 may include first connection members 171, first connection pads 172, and a first insulating member 174.

The first connection member 171 may electrically connect the first connection pad 172 to the first upper connection pad 133 of the baseband die 130. The first connection pad 172 may electrically connect the third redistribution layer via 192 of the second redistribution layer structure 190 to the first connection member 171.

The first insulating member 174 surrounds and protects the first connection members 171 and the first connection pads 172 between the baseband die 130 and the second redistribution layer structure 190. In an embodiment, the first insulating member 174 may be formed of or include a non-conductive film (NCF). In an embodiment, the first insulating member 174 may be formed of or include a molded underfill (MUF) material.

The second redistribution layer structure 190 may electrically connect the memory die 180 to the baseband die 130. The second redistribution layer structure 190 may include a second dielectric material layer 191, third redistribution layer vias 192, second redistribution layer lines 193, and fourth redistribution layer vias 194 within the second dielectric material layer 191. In another embodiment, the redistribution layer structure including fewer or greater numbers of redistribution layer lines and redistribution layer vias is included in the scope of the present disclosure . . .

The second dielectric material layer 191 protects and insulates the third redistribution layer vias 192, second redistribution layer lines 193, and fourth redistribution layer vias 194. The memory die 180 may be disposed on the upper surface of the second dielectric material layer 191. A first insulating member 174 and first connection pads 172 may be disposed on the lower surface of the second dielectric material layer 191.

The third redistribution layer via 192 may be disposed between the first connection pad 172 and the second redistribution layer line 193. The third redistribution layer via 192 may electrically connect the second redistribution layer line 193 to the first connection pad 172 in a vertical direction. The second redistribution layer line 193 may be disposed between the third redistribution layer via 192 and the fourth redistribution layer via 194. The second redistribution layer line 193 may electrically connect the third redistribution layer via 192 to the fourth redistribution layer via 194 in a horizontal direction. The fourth redistribution layer via 194 may be disposed between the second redistribution layer line 193 and the memory die 180. The fourth redistribution layer via 194 may electrically connect the memory die 180 to the second redistribution layer line 193 in a vertical direction.

The memory die 180 may be disposed on the second redistribution layer structure 190. The memory die 180 may be directly electrically connected to the baseband die 130 without a second redistribution layer structure 190. In an embodiment, the memory die 180 may be formed of or include DRAM or High Bandwidth Memory (HBM).

The conductive posts 150 may be disposed on the upper surface of the baseband die 130. The conductive post 150 may be disposed to pass through the first molding material 160. The side surface of the conductive post 150 may be surrounded by a first molding material 160. The conductive post 150 may electrically connect the second 3D integrated circuit structure 200 including the transceiver die 230 and radio communication die 280 to the baseband die 130.

The first molding material 160 may cover the conductive posts 150, the first interconnection connection structure 170, the memory die 180, and the second redistribution layer structure 190 on the baseband die 130. The first molding material 160 may serve to protect and insulate the conductive posts 150, the first interconnection connection structure 170, the memory die 180, and the second redistribution layer structure 190.

The first external connection structure 120 may include first conductive pads 121 and first external connection members 123. The first conductive pad 121 may electrically connect the first redistribution layer via 112 of the first redistribution layer structure 110 to the first external connection member 123. The first external connection member 123 may electrically connect the first 3D integrated circuit structure 100 to an external device. In an embodiment, the first external connection member 123 may be formed of or include a solder ball or a conductive bump.

The second 3D integrated circuit structure 200 may include a third redistribution layer structure 210, a transceiver die 230, a second interconnection connection structure 270, a fourth redistribution layer structure 290, a radio communication die 280, a second molding material 260, and a second external connection structure 220.

The third redistribution layer structure 210 may include a third dielectric material layer 211, fifth redistribution layer vias 212, third redistribution layer lines 213, and sixth redistribution layer vias 214 within the third dielectric material layer 211. In another embodiment, the redistribution layer structure including a smaller or larger number of redistribution layer lines and redistribution layer vias is included in the scope of the present disclosure.

The third dielectric material layer 211 protects and insulates the fifth redistribution layer vias 212, the third redistribution layer lines 213, and the sixth redistribution layer vias 214. The transceiver die 230 may be disposed on the upper surface of the third dielectric material layer 211, and the second external connection structure 220 may be disposed on the lower surface of the third dielectric material layer 211.

The fifth redistribution layer via 212 may be disposed between the third redistribution layer line 213 and the second conductive pad 221 of the second external connection structure 220. The fifth redistribution layer via 212 may electrically connect the third redistribution layer line 213 to the second conductive pad 221 in a vertical direction. The third redistribution layer line 213 may be disposed between the fifth redistribution layer via 212 and the sixth redistribution layer via 214. The third redistribution layer line 213 may electrically connect the fifth redistribution layer via 212 to the sixth redistribution layer via 214 in a horizontal direction. The sixth redistribution layer via 214 may be disposed between the third redistribution layer line 213 and the second lower connection pad 231 of the transceiver die 230. The sixth redistribution layer via 214 may electrically connect the second lower connection pad 231 of the transceiver die 230 to the third redistribution layer line 213 in a vertical direction. The sixth redistribution layer via 214 may be directly connected to the second lower connection pad 231 of the transceiver die 230 without any other connection member. In an embodiment, the fifth redistribution layer via 212 and the sixth redistribution layer via 214 may have the width of the uppermost portion smaller than the width of the lowermost portion.

The transceiver die 230 may include second lower connection pads 231, second through silicon vias (TSV) 232, second upper connection pads 233 and a transceiver chip 235.

The second lower connection pad 231 may be disposed between the second through silicon via (TSV) 232 and the sixth redistribution layer via 214. The second lower connection pad 231 may electrically connect the second through silicon via (TSV) 232 to the sixth redistribution layer via 214.

The second through silicon via (TSV) 232 may be disposed between the second lower connection pad 231 and the second upper connection pad 233. The second through silicon via (TSV) 232 may electrically connect the second upper connection pad 233 to the second lower connection pad 231. In the second 3D integrated circuit structure 200, since the radio communication die 280 is disposed away from a substrate that transmits thereto, and receives therefrom, a signal and a power, by disposing the second through silicon via (TSV) 232 in the transceiver die 230 and electrically connecting it to the radio communication die 280, the speed of receiving and responding to the signal and the power of the radio communication die 280 may be increased.

The second upper connection pad 233 may be disposed between the second through silicon via (TSV) 232 and the second connection member 271. The second upper connection pad 233 may electrically connect the second connection member 271 to the second through silicon via (TSV) 232.

The transceiver chip 235 may include a transmitter TX and a receiver RX. The transmitter TX may generate a first radio frequency (RF) signal and transmit the generated first radio frequency (RF) signal. The receiver RX may receive a second radio frequency (RF) signal and process the received second radio frequency (RF) signal. The transmitter TX and the receiver RX may be formed of or include processing circuitry, for example.

The second interconnection connection structure 270 may be disposed between the transceiver die 230 and the fourth redistribution layer structure 290. The second interconnection connection structure 270 may include second connection members 271, second connection pads 272, and a second insulating member 274. The second connection member 271 may electrically connect the second connection pad 272 to the second upper connection pad 233 of the transceiver die 230. The second connection pad 272 may electrically connect the seventh redistribution layer via 292 of the fourth redistribution layer structure 290 to the second connection member 271.

The second insulating member 274 surrounds and protects the second connection members 271 and the second connection pads 272 between the transceiver die 230 and the fourth redistribution layer structure 290. In an embodiment, the second insulating member 274 may be formed of or include a non-conductive film (NCF). In an embodiment, the second insulating member 274 may be formed of or include a molded underfill material (MUF).

The fourth redistribution layer structure 290 may electrically connect the radio communication die 280 to the transceiver die 230. The fourth redistribution layer structure 290 may include a fourth dielectric material layer 291, seventh redistribution layer vias 292, fourth redistribution layer lines 293, and eighth redistribution layer vias 294 within the fourth dielectric material layer 291. In another embodiment, the redistribution layer structure including fewer or greater numbers of redistribution layer lines and redistribution layer vias is included in the scope of the present disclosure.

The fourth dielectric material layer 291 protects and insulates the seventh redistribution layer vias 292, the fourth redistribution layer lines 293, and the eighth redistribution layer vias 294. The radio communication die 280 may be disposed on the upper surface of the fourth dielectric material layer 291. The second insulating member 274 and the second connection pads 272 may be disposed on the lower surface of the fourth dielectric material layer 291.

The seventh redistribution layer via 292 may be disposed between the second connection pad 272 and the fourth redistribution layer line 293. The seventh redistribution layer via 292 may electrically connect the fourth redistribution layer line 293 to the second connection pad 272 in a vertical direction. The fourth redistribution layer line 293 may be disposed between the seventh redistribution layer via 292 and the eighth redistribution layer via 294. The fourth redistribution layer line 293 may electrically connect the seventh redistribution layer via 292 to the eighth redistribution layer via 294 in a horizontal direction. The eighth redistribution layer via 294 may be disposed between the fourth redistribution layer line 293 and the radio communication die 280. The eighth redistribution layer via 294 may electrically connect the radio communication die 280 to the fourth redistribution layer line 293 in a vertical direction.

The radio communication die 280 may include a third lower connection pad 281, a third through silicon via (TSV) 282, a RFIC chip 283, a PIFA (planar inverted F antenna) antenna 285, and a patch antenna 286.

The first lower connection pad 281 may be disposed between the third through silicon via (TSV) 282 and the eighth redistribution layer via 294. The first lower connection pad 281 may electrically connect the third through silicon via (TSV) 282 to the eighth redistribution layer via 294.

A third through silicon via (TSV) 282 may be disposed between the third lower connection pad 281 and the PIFA antenna 285. The third through silicon via (TSV) 282 may electrically connect the PIFA antenna 285 to the third lower connection pad 281. The third through silicon via (TSV) 282 may be a feeding line. By implementing the feeding line as the third through silicon via (TSV) 282, the signal from the PIFA antenna 285 may be quickly transmitted.

The RFIC chip 283 is a chip that transmits and receives RF signals from the antenna and amplifies them. In the conventional antenna in package (AiP), the RFIC chip is disposed on the lower surface of the m-SAP substrate, and the distance between the antenna and the RFIC chip is long, so a problem that the signal is attenuated may occur in the process of transferring the received signal from the antenna to the RFIC chip. However, according to the present disclosure, the RFIC chip 283 is disposed on the radio communication die 280 of the second 3D integrated circuit structure 200, and the PIFA antenna 285 and the patch antenna 286 are directly disposed on the RFIC chip 283, thereby the distance between the RFIC chip 283 and the PIFA antenna 285, and between the RFIC chip 283 and the patch antenna 286 may be minimized and the signal attenuation may be reduced.

The PIFA antenna 285 may be disposed on the upper surface of the radio communication die 280, or disposed so that the side surface and the lower surface of the PIFA antenna 285 are embedded in the radio communication die 280 and the upper surface of the PIFA antenna 285 is exposed. The PIFA antenna 285 may be electrically connected to the third through silicon via (TSV) 282. In an embodiment, the PIFA antenna 285 may be formed of a metal having a pattern.

The patch antenna 286 may be disposed on the upper surface of the radio communication die 280, or disposed so that the side surface and the lower surface of the patch antenna 286 are embedded in the radio communication die 280 and the upper surface of the patch antenna 286 is exposed. In an embodiment, the patch antenna 286 may be formed of a metal having a pattern.

In the conventional antenna in package (AiP), the antennas are disposed on the upper surface of the m-SAP substrate, but according to the present disclosure, the PIFA antenna 285 and patch antenna 286 are directly disposed on the RFIC chip 283 in the radio communication die 280 among the second 3D integrated circuit structure 200, as described above, the distances between the RFIC chip 283 and the PIFA antenna 285, and between the RFIC chip 283 and the patch antenna 286 may be minimized and signal attenuation may be reduced.

The second molding material 260, on the transceiver die 230, may cover the second interconnection connection structure 270, the radio communication die 280, and the fourth redistribution layer structure 290. The second molding material 260 may cover the side surfaces of the second interconnection connection structure 270, the radio communication die 280, and the fourth redistribution layer structure 290. The upper surface of the radio communication die 280 may be exposed to the outside without being covered by the second molding material 260. The second molding material 260 may serve to protect and insulate the second interconnection connection structure 270, the radio communication die 280, and the fourth redistribution layer structure 290.

The second external connection structure 220 may include second conductive pads 221, second external connection members 223, and a third insulating member 224. The second conductive pad 221 may electrically connect the fifth redistribution layer via 212 of the third redistribution layer structure 210 to the second external connection member 223. The second external connection member 223 may electrically connect the second 3D integrated circuit structure 200 to the first 3D integrated circuit structure 100. In an embodiment, the second external connection member 223 may be formed of or include a solder ball or conductive bump. In an embodiment, the third insulating member 224 may be formed of or include a molded underfill material (MUF).

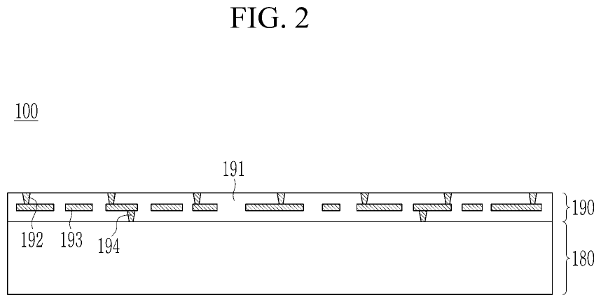

FIG. 2 is a cross-sectional view showing a step of forming a second redistribution layer structure 190 on a memory die 180 as one step among steps of a manufacturing method of a first 3D integrated circuit structure 100.

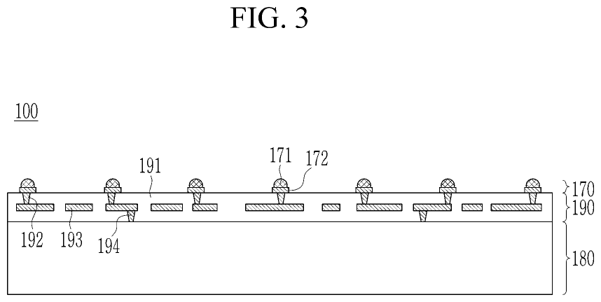

FIGS. 2 and 3 are cross-sectional views showing steps of forming a structure including first interconnection connection structure 170, second redistribution layer structure 190, and memory die 180 of a first 3D integrated circuit structure 100.

Referring to FIG. 2, a second redistribution layer structure 190 is formed on a memory die 180.

A second dielectric material layer 191 is formed on the memory die 180. In an embodiment, the second dielectric material layer 191 may be formed of or include a photoactive polymer layer. The photoactive polymer is a material that may form a fine pattern by applying a photolithography process. In an embodiment, the second dielectric material layer 191 may include a photo imageable dielectric (a photo imageable dielectric, PID) used in a redistribution layer process. As an embodiment, the photo imageable dielectric (PID) may include a polyimide-based photoactive polymer, a novolak-based photoactive polymer, polybenzoxazole, a silicon-based polymer, an acrylate-based polymer, or an epoxy-based polymer. In another embodiment, the second dielectric material layer 191 is formed of an inorganic dielectric material such as silicon nitride, silicon oxide, or the like. In an embodiment, the second dielectric material layer 191 may be formed by a CVD, an ALD, or a PECVD process.

After forming the second dielectric material layer 191, via holes are formed by selectively etching the second dielectric material layer 191, and fourth redistribution layer vias 194 are formed by filling the via holes with a conducting material. Among the fourth redistribution layer vias 194, the uppermost width of each fourth redistribution layer via is greater than the width of the lowermost via. In the subsequent process, since the memory die 180 on which the second redistribution layer structure 190 is formed is overturned to manufacture a final product, in the final product, the width of the uppermost portion of each fourth redistribution layer vias among the fourth redistribution layer vias 194 becomes smaller than the width of the lowermost portion.

Next, a second dielectric material layer 191 is additionally deposited on the fourth redistribution layer vias 194 and the second dielectric material layer 191, the additional deposited second dielectric material layer 191 is selectively etched to form openings, and the openings are filled with a conducting material to form second redistribution layer lines 193.

Next, a second dielectric material layer 191 is additionally deposited on the second redistribution layer lines 193 and the second dielectric material layer 191, the additional deposited second dielectric material layer 191 is selectively etched to form via holes, and the via holes are filled with a conducting material to form third redistribution layer vias 192. For the same reason as the fourth redistribution layer vias 194, in the final product, the width of the uppermost portion of each third redistribution layer vias 192 is smaller than the width of the lowermost portion.

In an embodiment, the third redistribution layer vias 192, the second redistribution layer lines 193, and the fourth redistribution layer vias 194 may be formed of or include at least one among copper, aluminum, tungsten, nickel, gold, tin, titanium, and alloys thereof. In an embodiment, the third redistribution layer vias 192, the second redistribution layer lines 193, and the fourth redistribution layer vias 194 may be formed by performing a sputtering process. In another embodiment, the third redistribution layer vias 192, the second redistribution layer lines 193, and the fourth redistribution layer vias 194 may be formed by performing an electrolytic plating process after forming a seed metal layer.

FIG. 3 is a cross-sectional view showing a step of forming a first interconnection structure 170 on a second redistribution layer structure 190 as one step among steps of a manufacturing method of a first 3D integrated circuit structure 100.

Referring to FIG. 3, on the second redistribution layer structure 190, a first interconnection connection structure 170 including first connection members 171 and first connection pads 172 is formed. In an embodiment, the first connection member 171 may include micro bumps. In an embodiment, the first connection member 171 may be formed of or include at least one of tin, silver, lead, nickel, copper and alloys thereof. In an embodiment, the first connection pad 172 may be formed by performing a sputtering process, or an electrolytic plating process after forming a seed metal layer. In an embodiment, first connection pad 172 may be formed of or include at least one of copper, aluminum, silver, tin, gold, nickel, lead, titanium, and alloys thereof.

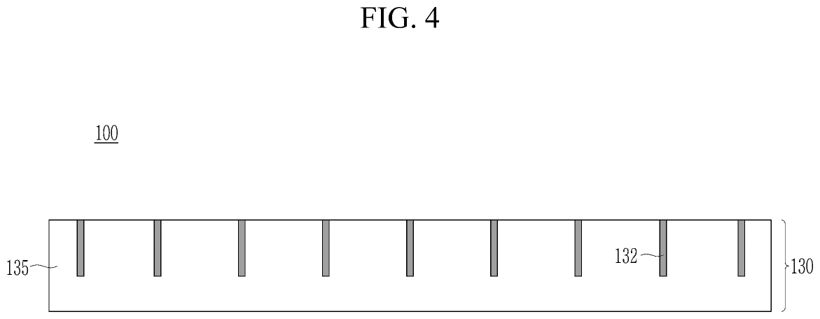

FIGS. 4-9 are cross-sectional views showing steps of forming a structure including first redistribution layer structure 110, baseband die 130, and first external connection structure 120 of a first 3D integrated circuit structure 100.

FIG. 4 is a cross-sectional view showing a step of forming first through silicon vias TSV 132 in a baseband die 130 as one step among steps of a manufacturing method of a first 3D integrated circuit structure 100.

Referring to FIG. 4, a first through silicon vias (TSV) 132 is formed on a baseband die 130 including a baseband chip 135. The first through silicon via (TSV) 132 is formed by forming holes penetrating an insulating material in the baseband die 130 and filling the holes with a conducting material. In an embodiment, the hole of the first through silicon via (TSV) 132 may be formed by a deep etching. In another embodiment, the hole of the first through silicon via (TSV) 132 may be formed by a laser. In an embodiment, the hole of first through silicon via (TSV) 132 may be filled with a conducting material by an electrolytic plating. In an embodiment, the first through silicon via (TSV) 132 may be formed of or include at least one of tungsten, aluminum, copper and their alloys.

A barrier layer may be formed between the first through silicon via (TSV) 132 and the insulating material of the baseband die 130. In an embodiment, the barrier layer may be formed of or include at least one of titanium, tantalum, titanium nitride, tantalum nitride and alloys thereof.

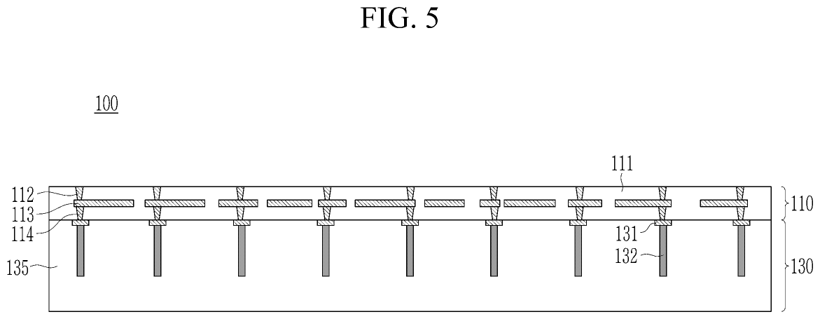

FIG. 5 is a cross-sectional view showing a step of forming a first redistribution layer structure 110 on a baseband die 130 as one step among steps of a manufacturing method of a first 3D integrated circuit structure 100.

Referring to FIG. 5, a first redistribution layer structure 110 is formed on the front side of the baseband die 130.

First, a first lower connection pad 131 is formed to be connected to

the first through silicon via (TSV) 132. In an embodiment, the first lower connection pad 131 may be formed by depositing a silicon layer and then performing a photo, development, etching and electrolytic plating. In an embodiment, the first lower connection pad 131 may be formed of or include at least one of copper, aluminum, silver, tin, gold, nickel, lead, titanium, and alloys thereof.

Then, a first dielectric material layer 111 is formed on the first lower connection pad 131 and the silicon layer or on the baseband die 130. Since the first dielectric material layer 111 is directly formed on the first lower connection pad 131 and the silicon layer or on the baseband die 130, connection members such as micro bumps and solder bumps are not used between the baseband die 130 and the first redistribution layer structure 110. In an embodiment, the first dielectric material layer 111 may be formed of or include a photoactive polymer layer. The photoactive polymer is a material that may form a fine pattern by applying a photolithography process. In an embodiment, the first dielectric material layer 111 may include a photo imageable dielectric (a photosensitive dielectric; PID) used in a redistribution layer process. As an embodiment, the photo imageable dielectric (PID) may include a polyimide-based photoactive polymer, a novolac-based photoactive polymer, polybenzoxazole, a silicon-based polymer, an acrylate-based polymer, or an epoxy-based polymer. In another embodiment, the first dielectric material layer 111 is formed of an inorganic dielectric material such as silicon nitride, silicon oxide, or the like. In an embodiment, the first dielectric material layer 111 may be formed by a CVD, ALD, or a PECVD process.

After forming the first dielectric material layer 111, via holes are formed by selectively etching the first dielectric material layer 111, and second redistribution layer vias 114 are formed by filling the via holes with a conducting material. The width of the uppermost portion of each of the second redistribution layer vias 114 is greater than the width of the lowermost portion of the second redistribution layer vias. In the subsequent process, since the baseband die 130 on which the first redistribution layer structure 110 is formed is overturned to produce the final product, in the final product, the width of the uppermost portion of each second redistribution layer vias 114 is smaller than the width of the lowermost portion.

Then, a first dielectric material layer 111 is additionally deposited on the second redistribution layer vias 114 and the first dielectric material layer 111, the additionally deposited first dielectric material layer 111 is selectively etched to form openings, and the openings are filled with a conducting material to form first redistribution layer lines 113.

Then, a first dielectric material layer 111 is additionally deposited on the first redistribution layer lines 113 and the first dielectric material layer 111, the additionally deposited first dielectric material layer 111 is selectively etched to form via holes, and a conducting material is filled in the via holes to form first redistribution layer vias 112. For the same reason as the second redistribution layer vias 114, in the final product, the width of the uppermost portion of each of the first redistribution layer vias 112 is smaller than the width of the lowermost portion.

In an embodiment, the first redistribution layer vias 112, the first redistribution layer lines 113, and the second redistribution layer vias 114 may be formed of or include at least one of copper, aluminum, tungsten, nickel, gold, tin, titanium and their alloys. In an embodiment, the first redistribution layer vias 112, the first redistribution layer lines 113, and the second redistribution layer vias 114 may be formed by performing a sputtering process. In another embodiment, the first redistribution layer vias 112, the first redistribution layer lines 113, and the second redistribution layer vias 114 may be formed by performing an electrolytic plating process after forming a seed metal layer.

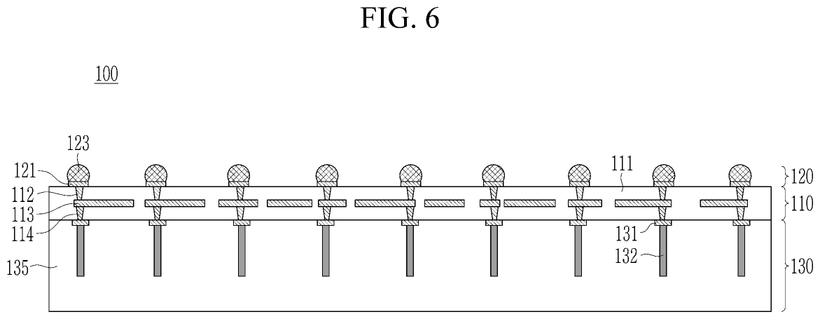

FIG. 6 is a cross-sectional view showing a step of forming a first external connection structure 120 on a first redistribution layer structure 110 as one step among steps of a manufacturing method of a first 3D integrated circuit structure 100.

Referring to FIG. 6, a first external connection structure 120 is formed on the first redistribution layer structure 110. First conductive pads 121 are formed on the first dielectric material layer 111 of the first redistribution layer structure 110, and a first external connection member 123 is formed on the first conductive pads 121. In an embodiment, the first conductive pad 121 may be formed of or include at least one of copper, nickel, zinc, gold, silver, platinum, palladium, chromium, titanium and alloys thereof. In an embodiment, the first conductive pad 121 may be formed by performing a sputtering process, or an electrolytic plating process after forming a seed metal layer. In an embodiment, the first external connection member 123 may include at least one of tin, silver, lead, nickel, copper, or an alloy thereof.

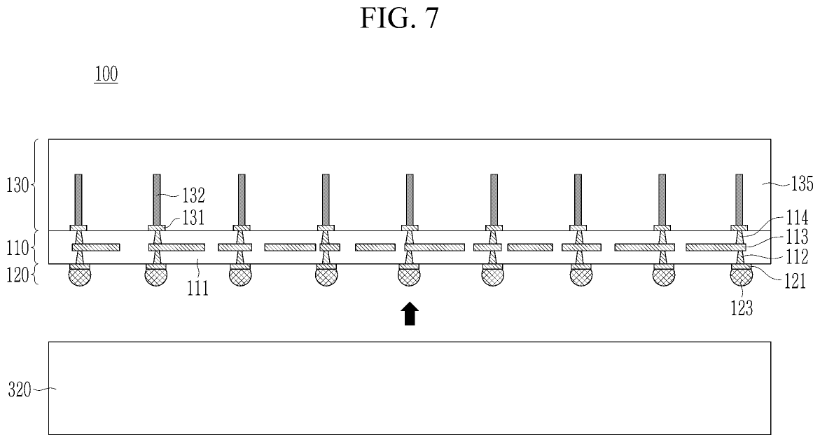

FIG. 7 is a cross-sectional view showing a step of bonding a first carrier 320 under a first redistribution layer structure 110 and a first external connection structure 120 as one step among steps of a manufacturing method of a first 3D integrated circuit structure 100.

Referring to FIG. 7, the baseband die 130 on which the first redistribution layer structure 110 and the first external connection structure 120 are formed is overturned and aligned, and a first carrier 320 is bonded under the first redistribution layer structure 110 and the first external connection structure 120. The first carrier 320 may be formed of or include, for example, a silicon-based material such as glass or silicon oxide, an organic material, or another material such as aluminum oxide, any combination of these materials, and the like.

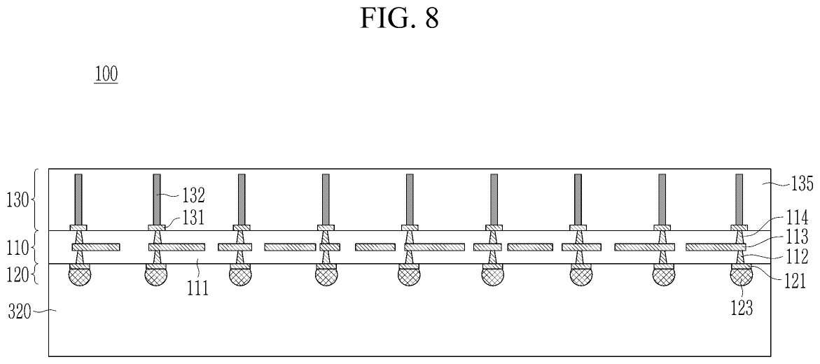

FIG. 8 is a cross-sectional view showing a step of grinding a back side of a baseband die 130 as one step among steps of a manufacturing method of a first 3D integrated circuit structure 100.

Referring to FIG. 8, the back side of the baseband die 130 is grinded to be removed.

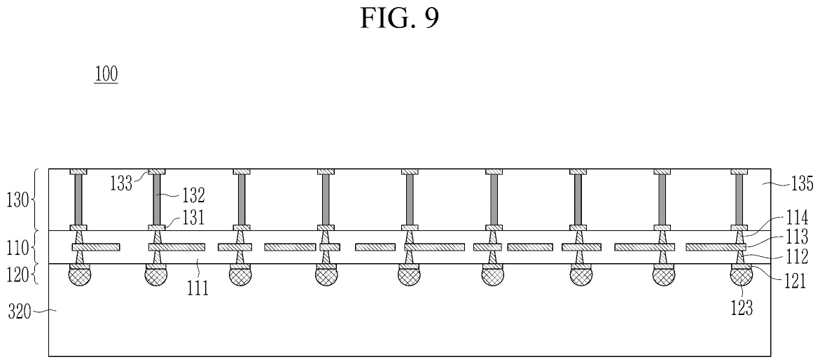

FIG. 9 is a cross-sectional view showing a step of forming first upper connection pads 133 on a back side of a baseband die 130 as one step among steps of a manufacturing method of a first 3D integrated circuit structure 100.

Referring to FIG. 9, the first upper connection pad 133 is formed to be connected to the first through silicon via (TSV) 132. In an embodiment, the first upper connection pad 133 may be formed on the back side of the baseband die 130 by performing a photo, development, etching. and electrolytic plating. In an embodiment, the first upper connection pad 133 may be formed of or include at least one of copper, aluminum, silver, tin, gold, nickel, lead, titanium, and alloys thereof.

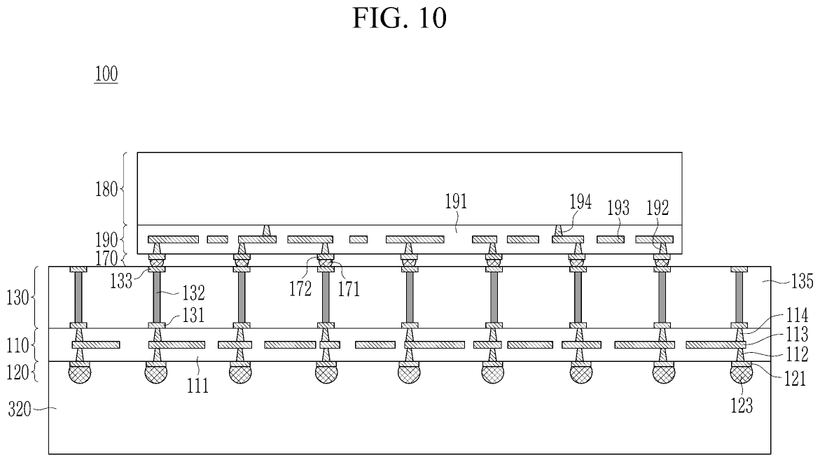

FIGS. 10-16 are cross-sectional views showing steps of combining a memory die 180 with a baseband die 130 to form first 3D integrated circuit structure 100.

FIG. 10 is a cross-sectional view showing a step of mounting a memory die 180 on which a second redistribution layer structure 190 is formed on a baseband die 130 as one step among steps of a manufacturing method of a first 3D integrated circuit structure 100.

Referring to FIG. 10, a memory die 180 on which a second redistribution layer structure 190 is formed is mounted on a baseband die 130 by using first connection members 171.

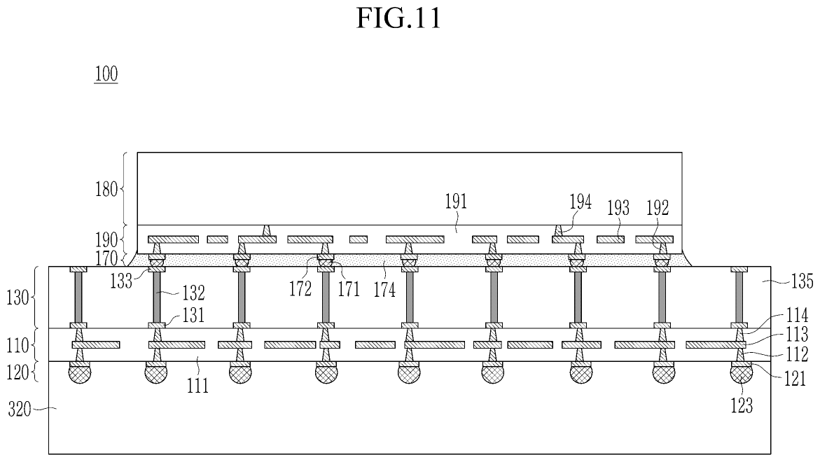

FIG. 11 is a cross-sectional view showing a step of forming a first insulating member 174 between a baseband die 130 and a second redistribution layer structure 190 as one step among steps of a manufacturing method of a first 3D integrated circuit structure 100.

Referring to FIG. 11, a first insulating member 174 is disposed between the baseband die 130 and the second redistribution layer structure 190 to surround the first connection members 171 and the first connection pads 172. In this way, by adding the first insulating member 174, a stress between the baseband die 130 and the second redistribution layer structure 190 may be relieved. In an embodiment, the first insulating member 174 may be formed of or include a molded under-fill (MUF) material.

In another embodiment, before mounting the memory die 180 on which the second redistribution layer structure 190 is formed on the baseband die 130, a non-conductive film (NCF) may be attached as a first insulating member 174 on the baseband die 130. The non-conductive film (NCF) has adhesiveness and is attached on the baseband die 130. The non-conductive film (NCF) has an uncured state that may be deformed by an external force. The non-conductive film (NCF) may be attached by heating at a temperature of about 170° C. to about 300° C. for about 1 second to about 20 seconds. Then, the memory die 180 on which the second redistribution layer structure 190 is formed is stacked on the non-conductive film (NCF). The first connection member 171 provided in the second redistribution layer structure 190 penetrates the non-conductive film (NCF) to contact the first upper connection pad 133 of the baseband die 130.

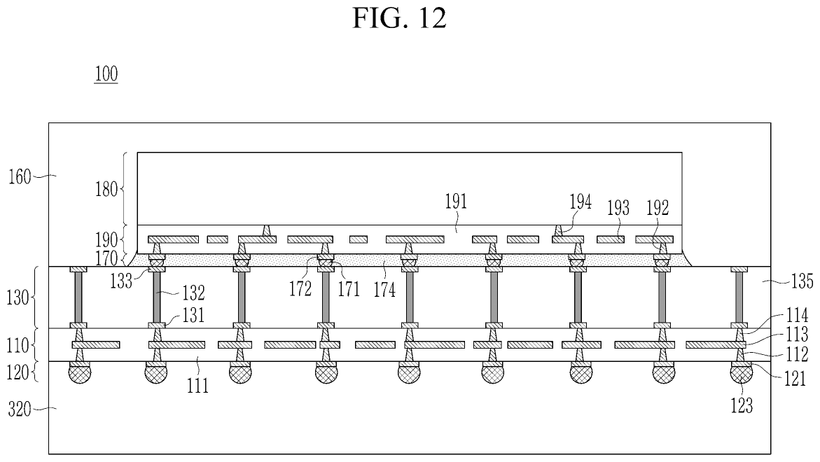

FIG. 12 is a cross-sectional view showing a step of covering a memory die 180 on which a second redistribution layer structure 190 is formed with a first molding material on a baseband die 130 as one step among steps of a manufacturing method of a first 3D integrated circuit structure 100.

Referring to FIG. 12, on the baseband die 130, the memory die 180 on which the second redistribution layer structure 190 is formed is covered with a first molding material 160. As an embodiment, a molding process with the first molding material 160 may include a compression molding or a transfer molding process. In an embodiment, the first molding material 160 may be an epoxy molding compound (EMC). In another embodiment, the first molding material 160 may be formed of a thermosetting resin such as an epoxy resin.

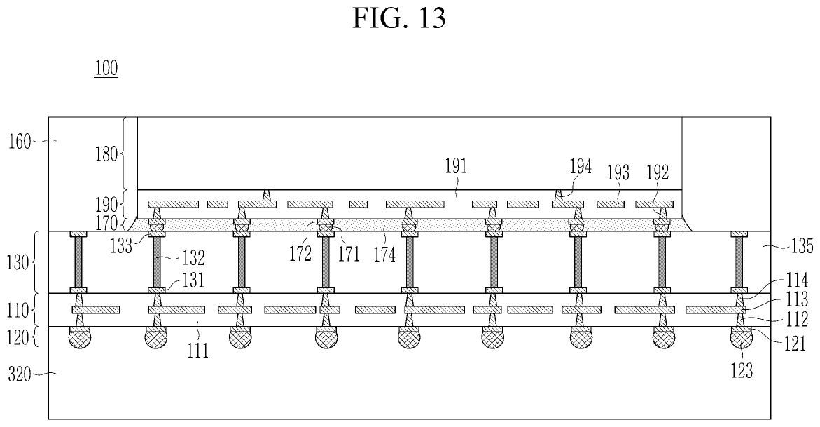

FIG. 13 is a cross-sectional view showing a step of planarizing a first molding material 160 as one step among steps of a manufacturing method of a first 3D integrated circuit structure 100.

Referring to FIG. 13, a chemical mechanical polishing (CMP) is performed to match the level of the upper surface of the first molding material 160 with the level of the upper surface of the memory die 180. The upper surface of the first molding material 160 is planarized by applying the CMP process.

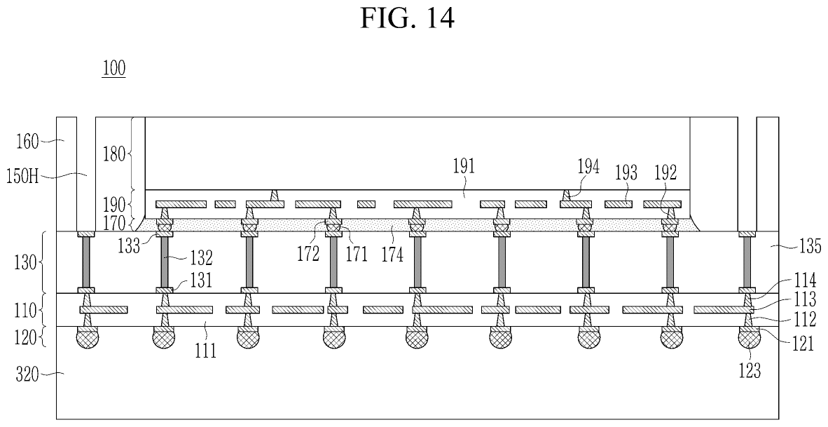

FIG. 14 is a cross-sectional view showing a step of forming through holes 150H in a first molding material 160 to form conductive posts 150 as one step among steps of a manufacturing method of a first 3D integrated circuit structure 100.

Referring to FIG. 14, through holes 150H are formed within the first molding material 160. In an embodiment, the through hole 150H may be formed by a laser drilling. In an embodiment, the laser drilling may be performed with a carbon dioxide (CO2) laser, an ultraviolet (Ultraviolet; UV) laser or an excimer laser. In an embodiment, the through hole 150H may be formed by a mechanical drilling. In an embodiment, the through hole 150H may be formed on the first molding material 160 by performing a photo, development, and etching.

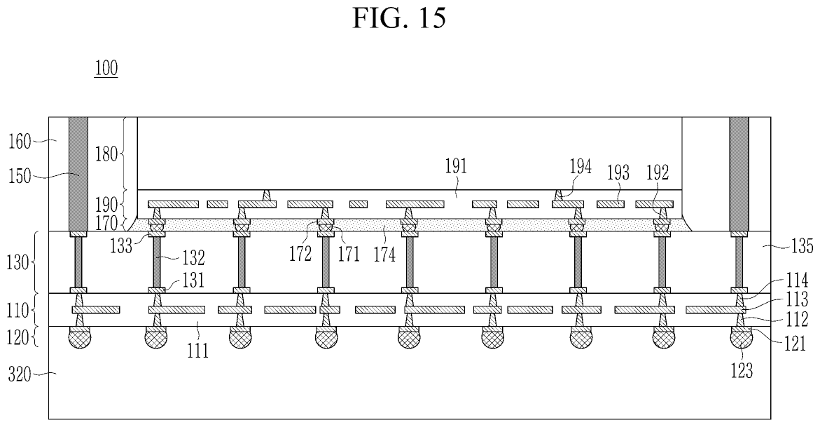

FIG. 15 is a cross-sectional view showing a step of forming conductive posts 150 by filling through holes 150H with a conductive material as one step among steps of a manufacturing method of a first 3D integrated circuit structure 100.

Referring to FIG. 15, the through holes 150H are filled with a conductive material to form the conductive posts 150. In an embodiment, the conductive material may be formed of or include a conductive paste. In an embodiment of filling the through holes 150H with a conductive paste, the through holes 150H may be filled with the conductive paste by a method of pressing the conductive paste into the through holes 150H by using a conductive paste print. In another embodiment, the conductive material may include copper or copper alloy. In an embodiment of filling the through holes 150H with copper or copper alloy, a seed metal layer may be deposited within the through holes 150H, and an electrolytic plating may be performed to fill the through holes 150H with copper or copper alloy. In another embodiment, the through hole 150H may be filled by performing a sputtering process. In an embodiment, the conductive posts 150 may be formed of or include at least one of copper, aluminum, tungsten, nickel, gold, silver, chromium, antimony, tin, titanium and alloys thereof.

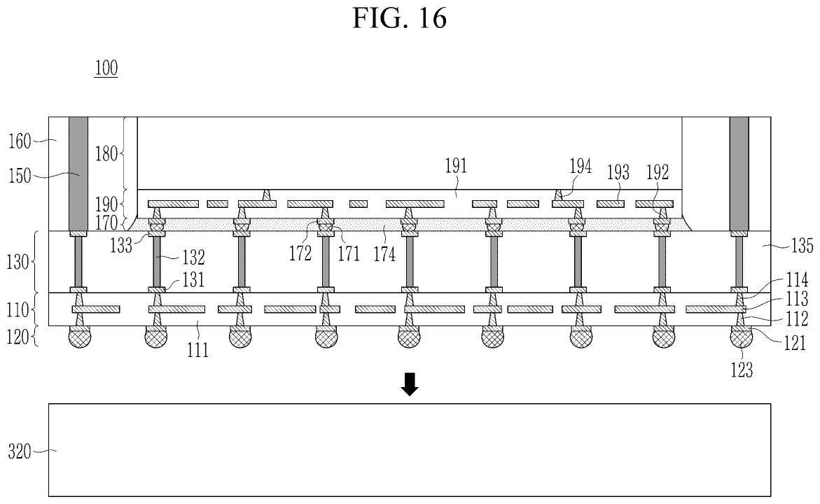

FIG. 16 is a cross-sectional view showing a step of de-bonding a first carrier 320 from a first redistribution layer structure 110 and a first external connection structure 120 as one step among steps of a manufacturing method of a first 3D integrated circuit structure 100.

Referring to FIG. 16, a first carrier 320 is removed from the first redistribution layer structure 110 and the first external connection structure 120.

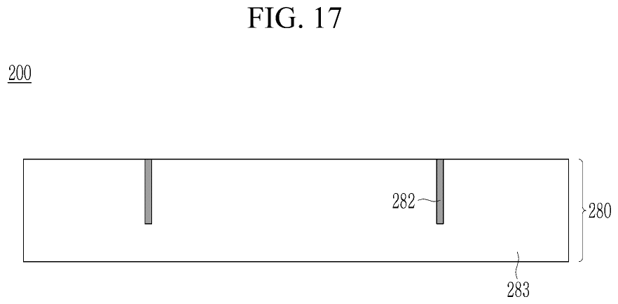

FIGS. 17-23 are cross-sectional views showing steps of forming a structure including a radio communication die 280, a fourth redistribution layer structure 290, and a second interconnection connection structure 270 of a second 3D integrated circuit structure 200.

FIG. 17 is a cross-sectional view showing a step of forming third through silicon vias (TSV) 282 in a radio communication die 280 as one step among steps of a manufacturing method of a second 3D integrated circuit structure 200.

Referring to FIG. 17, third through silicon vias (TSV) 282 are formed in the radio communication die 280. The third through silicon via (TSV) 282 is formed by forming holes penetrating an insulating material in the radio communication die 280 and filling the holes with a conducting material. In an embodiment, the hole of the third through silicon via (TSV) 282 may be formed by a deep etching. In another embodiment, the hole of the third through silicon via (TSV) 282 may be formed by a laser. In an embodiment, the holes of third through silicon via (TSV) 282 may be filled with a conducting material by an electrolytic plating. In an embodiment, the third through silicon via (TSV) 282 may be formed of or include at least one of tungsten, aluminum, copper and their alloys.

A barrier layer may be formed between the third through silicon via (TSV) 282 and the insulating material of the radio communication die 280. In an embodiment, the barrier layer may be formed of or include at least one of titanium, tantalum, titanium nitride, tantalum nitride and alloys thereof.

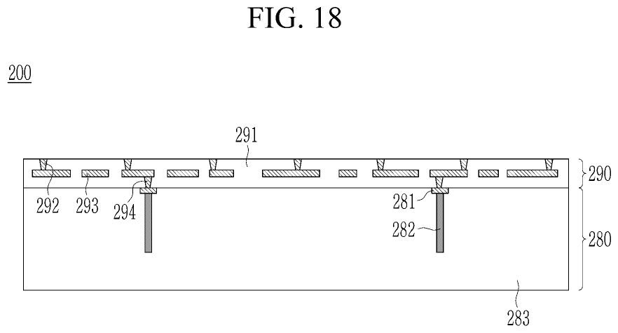

FIG. 18 is a cross-sectional view showing a step of forming a fourth redistribution layer structure 290 on a radio communication die 280 as one step among steps of a manufacturing method of a second 3D integrated circuit structure 200.

Referring to FIG. 18, a fourth redistribution layer structure 290 is formed on the radio communication die 280.

First, third lower connection pads 281 are formed to be connected to the third through silicon via (TSV) 282. In an embodiment, the third lower connection pad 281 may be formed by forming a silicon layer and then performing a photo, development, etching, and electrolytic plating. In an embodiment, the third lower connection pad 281 may be formed of or include at least one of copper, aluminum, silver, tin, gold, nickel, lead, titanium, and alloys thereof.

Next, a fourth dielectric material layer 291 is formed on the radio communication die 280. In an embodiment, the fourth dielectric material layer 291 may be formed of or include a photoactive polymer layer. A photoactive polymer is a material that can form a fine pattern by applying a photolithography process. In an embodiment, the fourth dielectric material layer 291 may include a photo imageable dielectric (photosensitive dielectric; PID) used in a redistribution layer process. As an embodiment, the photo imageable dielectric (PID) may include a polyimide-based photoactive polymer, a novolak-based photoactive polymer, polybenzoxazole, a silicon-based polymer, an acrylate-based polymer, or an epoxy-based polymer. In another embodiment, the fourth dielectric material layer 291 is formed of an inorganic dielectric material such as silicon nitride, silicon oxide, or the like. In an embodiment, the fourth dielectric material layer 291 may be formed by a CVD, ALD, or PECVD process.

After forming the fourth dielectric material layer 291, via holes are formed by selectively etching the fourth dielectric material layer 291, and eighth redistribution layer vias 294 are formed by filling the via holes with a conducting material. Of the eighth redistribution layer vias 294, the width of the uppermost portion of each eighth redistribution layer via is greater than the width of the lowermost portion. In the subsequent process, since the radio communication die 280 on which the fourth redistribution layer structure 290 is formed is overturned to manufacture the final product, in the final product, the width of the uppermost portion of each eighth redistribution layer vias 294 is smaller than the width of the lowermost portion.

Next, a fourth dielectric material layer 291 is additionally deposited on the eighth redistribution layer vias 294 and the fourth dielectric material layer 291, the additionally deposited fourth dielectric material layer 291 is selectively etched to form openings, and the openings are filled with a conducting material to form fourth redistribution layer lines 293.

Then, a fourth dielectric material layer 291 is additionally deposited on the fourth redistribution layer lines 293 and the fourth dielectric material layer 291, the additionally deposited fourth dielectric material layer 291 is selectively etched to form via holes, and a conducting material is filled in the via holes to form seventh redistribution layer vias 292. For the same reason as the eighth redistribution layer vias 294, in the final product, the width of the uppermost portion of each seventh redistribution layer vias 292 is smaller than the width of the lowermost portion.

In an embodiment, the seventh redistribution layer vias 292, the fourth redistribution layer lines 293, and the eighth redistribution layer vias 294 may be formed of or include at least one of copper, aluminum, tungsten, nickel, gold, tin, titanium and their alloys. In an embodiment, the seventh redistribution layer vias 292, the fourth redistribution layer lines 293, and the eighth redistribution layer vias 294 may be formed by performing a sputtering process. In another embodiment, the seventh redistribution layer vias 292, the fourth redistribution layer lines 293, and the eighth redistribution layer vias 294 may be formed by performing an electrolytic plating process after forming a seed metal layer.

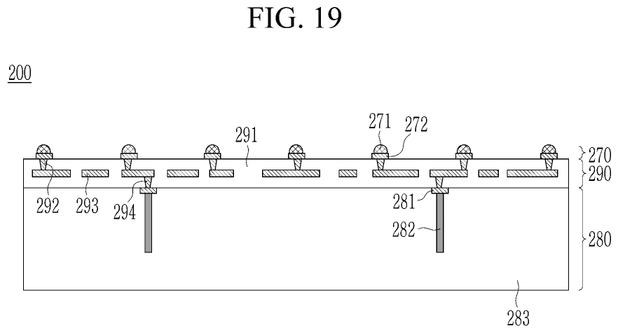

FIG. 19 is a cross-sectional view showing a step of forming a second interconnection connection structure 270 on a fourth redistribution layer structure 290 as one step among steps of a manufacturing method of a second 3D integrated circuit structure 200.

Referring to FIG. 19, a second interconnection connection structure 270 including second connection members 271 and second connection pads 272 is formed on the fourth redistribution layer structure 290. In an embodiment, the second connection member 271 may include micro bumps. In an embodiment, the second connection member 271 may be formed of or include at least one of tin, silver, lead, nickel, copper and alloys thereof. In an embodiment, the second connection pad 272 may be formed by performing a sputtering process, or an electrolytic plating process after forming a seed metal layer. In an embodiment, the second connection pad 272 may be formed of or include at least one of copper, aluminum, silver, tin, gold, nickel, lead, titanium, and alloys thereof.

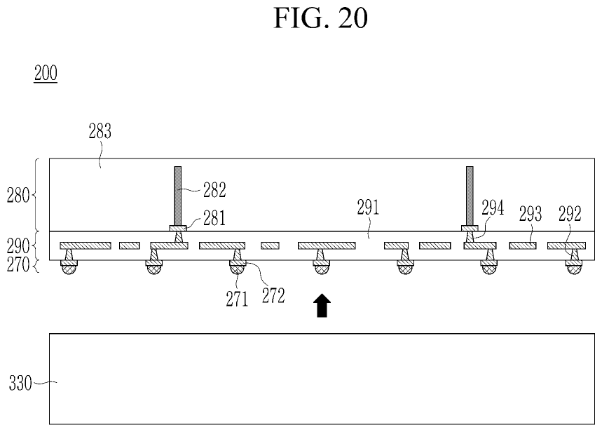

FIG. 20 is a cross-sectional view showing a step of bonding a second carrier 330 under a second interconnection connection structure 270 and a fourth redistribution layer structure 290 as one step among steps of a manufacturing method of a second 3D integrated circuit structure 200.

Referring to FIG. 20, the radio communication die 280 on which the second interconnection connection structure 270 and the fourth redistribution layer structure 290 are formed is overturned and aligned, and the second carrier 330 is bonded under the second interconnection connection structure 270 and the fourth redistribution layer structure 290. The second carrier 330 may be formed of or include, for example, a silicon-based material such as glass or silicon oxide, an organic material, or another material such as aluminum oxide, any combination of these materials, and the like.

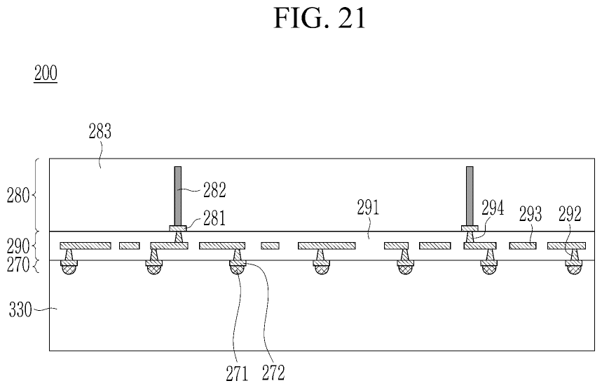

FIG. 21 is a cross-sectional view showing a step of grinding a back side of a radio communication die 280 as one step among steps of a manufacturing method of a second 3D integrated circuit structure 200.

Referring to FIG. 21, the back side of the radio communication die 280 is grinded to be removed.

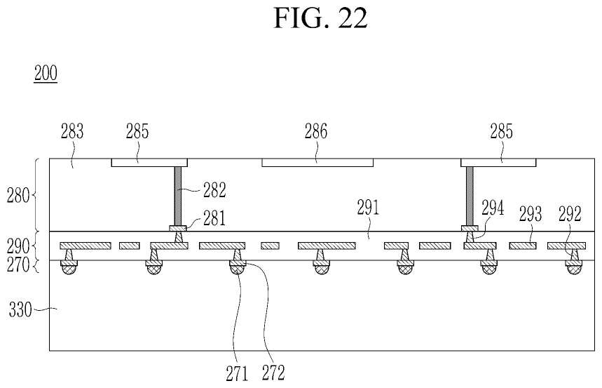

FIG. 22 is a cross-sectional view showing a step of attaching antennas on a back side of a radio communication die 280 as one step among steps of a manufacturing method of a second 3D integrated circuit structure 200.

Referring to FIG. 22, PIFA antennas 285 are attached on the back side of the radio communication die 280 to be connected to the third through silicon via (TSV) 282, and patch antennas 286 are attached on the back side of the radio communication die 280.

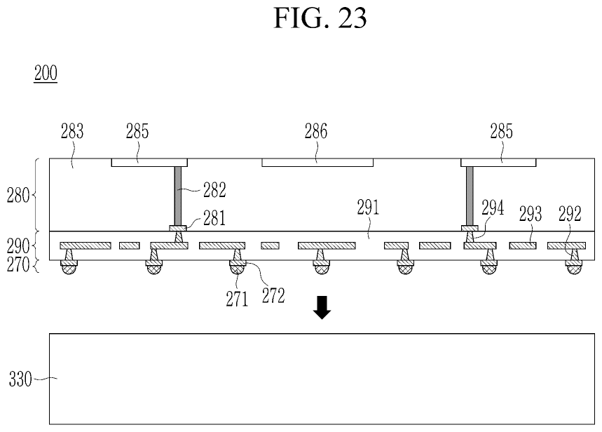

FIG. 23 is a cross-sectional view showing a step of de-bonding a second carrier 330 from a second interconnection connection structure 270 and a fourth redistribution layer structure 290 as one step among steps of a manufacturing method of a second 3D integrated circuit structure 200.

Referring to FIG. 23, the second carrier 330 is removed from the second interconnection connection structure 270 and the fourth redistribution layer structure 290.

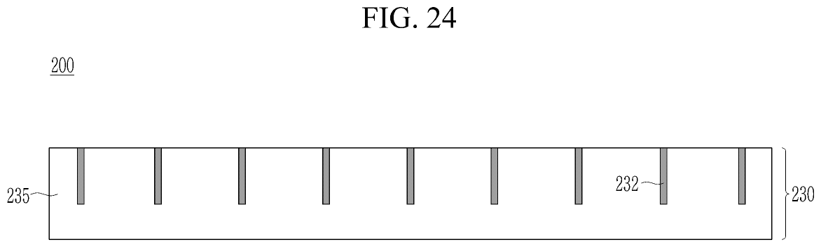

FIGS. 24-29 are cross-sectional views showing steps of forming a structure including a transceiver die 230, a third redistribution layer structure 210, and a second external connection structure 220 of a second 3D integrated circuit structure 200.

FIG. 24 is a cross-sectional view showing a step of forming second through silicon vias (TSV) 232 in a transceiver die 230 as one step among steps of a manufacturing method of a second 3D integrated circuit structure 200.

Referring to FIG. 24, the second through silicon vias (TSV) 232 are formed on the transceiver die 230. The second through silicon via (TSV) 232 is formed by forming holes penetrating an insulating material in the transceiver die 230 and filling the holes with a conducting material. In an embodiment, the holes of the second through silicon via (TSV) 232 may be formed by a deep etching. In another embodiment, the holes in the second through silicon via (TSV) 232 may be formed by a laser. In an embodiment, the holes of the second through silicon via (TSV) 232 may be filled with a conducting material by an electrolytic plating. In an embodiment, the second through silicon via (TSV) 232 may be formed of or include at least one of tungsten, aluminum, copper and their alloys.

A barrier layer may be formed between the second through silicon via (TSV) 232 and the insulating material of the transceiver die 230. In an embodiment, the barrier layer may be formed of or include at least one of titanium, tantalum, titanium nitride, tantalum nitride and alloys thereof.

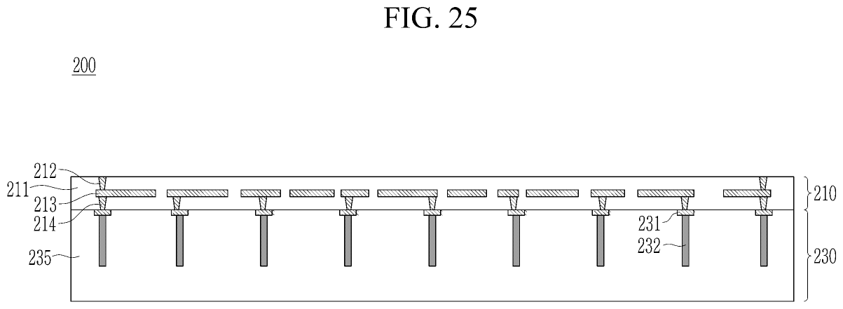

FIG. 25 is a cross-sectional view showing a step of forming a third redistribution layer structure 210 on a transceiver die 230 as one step among steps of a manufacturing method of a second 3D integrated circuit structure 200.

Referring to FIG. 25, a third redistribution layer structure 210 is formed on the front side of the transceiver die 230.

First, a second lower connection pad 231 is formed to be connected to the second through silicon via (TSV) 232. In an embodiment, the second lower connection pad 231 may be formed by depositing a silicon layer and then performing a photo, development, etching and electrolytic plating. In an embodiment, the second lower connection pad 231 may be formed of or include at least one of copper, aluminum, silver, tin, gold, nickel, lead, titanium, and alloys thereof.

Then, a third dielectric material layer 211 is formed on the second lower connection pad 231 and the silicon layer, or on the transceiver die 230. Since the third dielectric material layer 211 is formed directly on the second lower connection pad 231 and the silicon layer or on the transceiver die 230, connection members such as micro bumps and solder bumps are not used between the transceiver die 230 and the third redistribution layer structure 210. In an embodiment, the third dielectric material layer 211 may be formed of or include a photoactive polymer layer. A photoactive polymer is a material that may form a fine pattern by applying a photolithography process. In an embodiment, the third dielectric material layer 211 may include a photo imageable dielectric (a photosensitive dielectric; PID) used in a redistribution layer process. As an embodiment, the photo imageable dielectric (PID) may include a polyimide-based photoactive polymer, a novolac-based photoactive polymer, polybenzoxazole, a silicon-based polymer, an acrylate-based polymer, or an epoxy-based polymer. In another embodiment, the third dielectric material layer 211 is formed of an inorganic dielectric material such as silicon nitride, silicon oxide, or the like. In an embodiment, the third dielectric material layer 211 may be formed by a CVD, ALD, or PECVD process.

After forming the third dielectric material layer 211, the third dielectric material layer 211 is selectively etched to form via holes, and the via holes are filled with a conducting material to form the sixth redistribution layer vias 214. The width of an uppermost portion of each of the sixth redistribution layer vias 214 is greater than the width of a lowermost portion of the sixth redistribution layer vias. In the subsequent process, since the transceiver die 230 on which the third redistribution layer structure 210 is formed is overturned to produce the final product, in the final product, the width of the uppermost portion of each of the sixth redistribution layer vias 214 is smaller than the width of the lowermost portion.

Then, a third dielectric material layer 211 is additionally deposited on the sixth redistribution layer vias 214 and the third dielectric material layer 211, the additionally deposited third dielectric material layer 211 is selectively etched to form openings, and the openings are filled with a conducting material to form third redistribution layer lines 213.

Then, a third dielectric material layer 211 is additionally deposited on the third redistribution layer lines 213 and the third dielectric material layer 211, the additionally deposited third dielectric material layer 211 is selectively etched to form via holes, and a conducting material is filled in the via holes to form fifth redistribution layer vias 212. For the same reason as the sixth redistribution layer vias 214, in the final product, the width of the uppermost portion of each fifth redistribution layer vias 212 is smaller than the width of the lowermost portion.

In an embodiment, the fifth redistribution layer vias 212, the fourth redistribution layer lines 213, and the sixth redistribution layer vias 214 may be formed of or include at least one of copper, aluminum, tungsten, nickel, gold, tin, titanium and their alloys. In an embodiment, the fifth redistribution layer vias 212, the third redistribution layer lines 213, and the sixth redistribution layer vias 214 may be formed by performing a sputtering process. In another embodiment, the fifth redistribution layer vias 212, the third redistribution layer lines 213, and the sixth redistribution layer vias 214 may be formed by performing an electrolytic plating process after forming a seed metal layer.

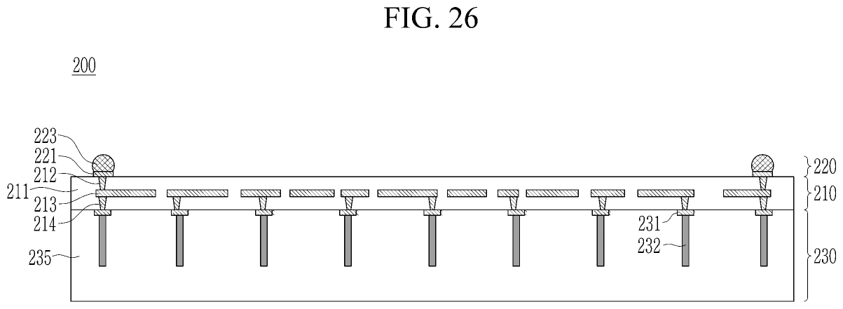

FIG. 26 is a cross-sectional view showing a step of forming a second external connection structure 220 on a third redistribution layer structure 210 as one step among steps of a manufacturing method of a second 3D integrated circuit structure 200.

Referring to FIG. 26, a second external connection structure 220 is formed on the third redistribution layer structure 210. Second conductive pads 221 are formed on the third dielectric material layer 211 of the third redistribution layer structure 210, and a second external connection member 223 is formed on the second conductive pad 221. In an embodiment, the second conductive pad 221 may be formed of or include at least one of copper, nickel, zinc, gold, silver, platinum, palladium, chromium, titanium and alloys thereof. In an embodiment, the second conductive pad 221 may be formed by performing a sputtering process, or an electrolytic plating process after forming a seed metal layer. In an embodiment, the second external connection member 223 may be formed of or include at least one of tin, silver, lead, nickel, copper, or an alloy thereof.

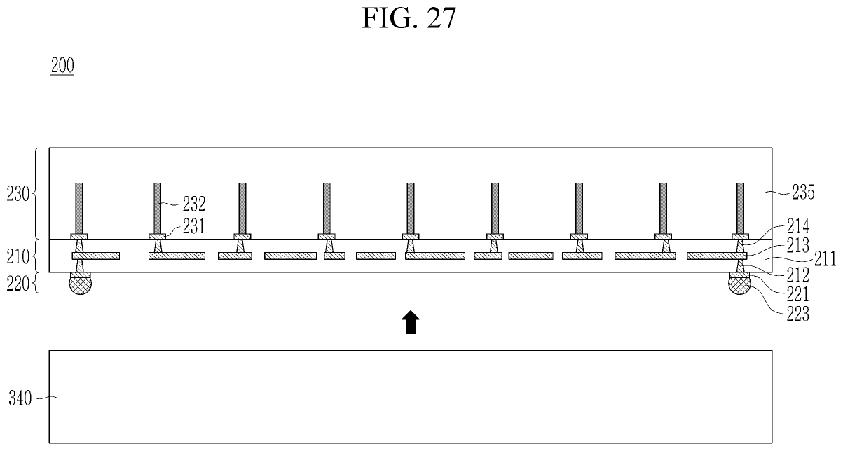

FIG. 27 is a cross-sectional view showing a step of bonding a third carrier 340 under a third redistribution layer structure 210 and a second external connection structure 220 as one step among steps of a manufacturing method of a second 3D integrated circuit structure 200.

referring to FIG. 27, the transceiver die 230 on which the third redistribution layer structure 210 and the second external connection structure 220 are formed is overturned and aligned, and a third carrier 340 is bonded under the second external connection structure 220. The third carrier 340 may be formed of or include, for example, a silicon-based material such as glass or silicon oxide, an organic material, or another material such as aluminum oxide, any combination of these materials, and the like.

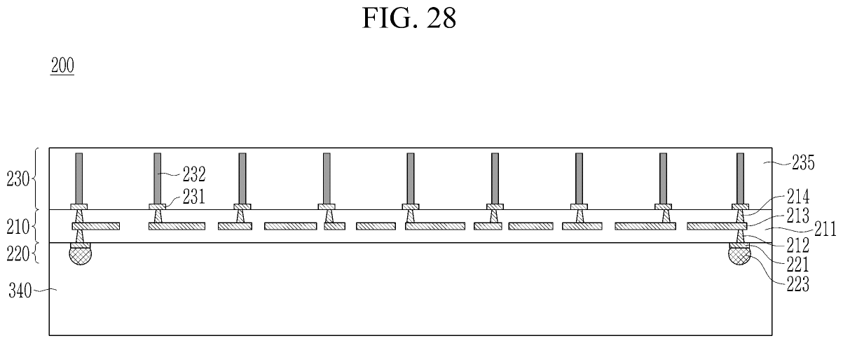

FIG. 28 is a cross-sectional view showing a step of grinding a back side of a transceiver die 230 as one step among steps of a manufacturing method of a second 3D integrated circuit structure 200.

Referring to FIG. 28, the back side of the transceiver die 230 is grinded to be removed.

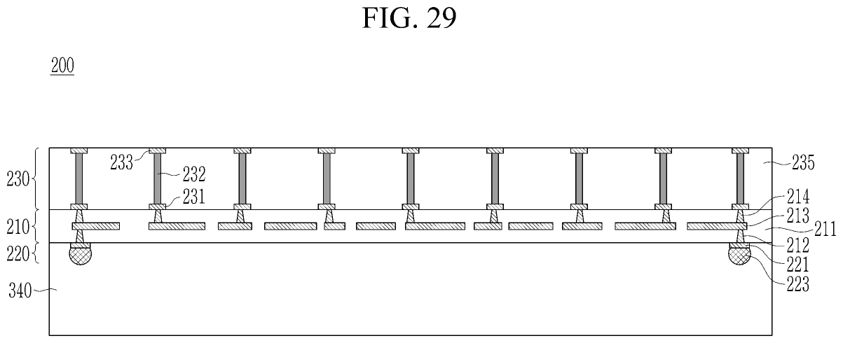

FIG. 29 is a cross-sectional view showing a step of forming second upper connection pads 233 on a back side of a transceiver die 230 as one step among steps of a manufacturing method of a second 3D integrated circuit structure 200.

Referring to FIG. 29, the second upper connection pad 233 is formed to be connected to the second through silicon via (TSV) 232. In an embodiment, the second upper connection pad 233 may be formed on the back side of the transceiver die 230 by performing a photo, development, etching and electrolytic plating. In an embodiment, the second upper connection pad 233 may be formed of or include at least one of copper, aluminum, silver, tin, gold, nickel, lead, titanium, and alloys thereof.

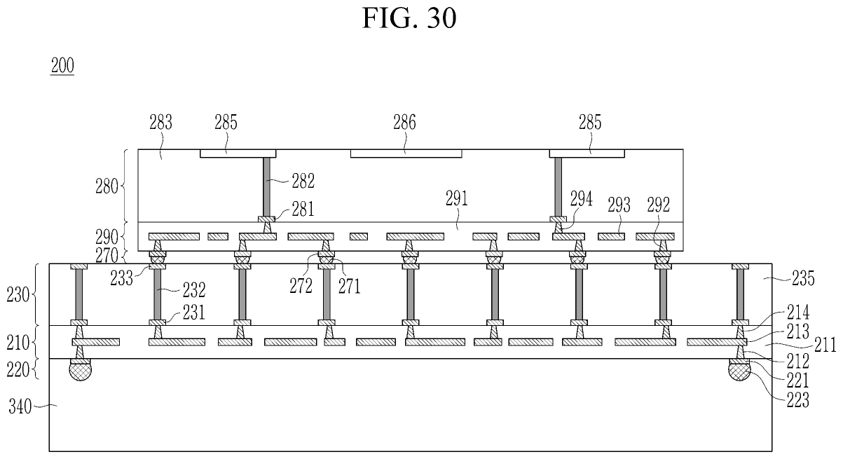

FIGS. 30-34 are cross-sectional views showing steps of combining a radio communication die 280 and a transceiver die 230 to form a second 3D integrated circuit structure 200.

FIG. 30 is a cross-sectional view showing a step of mounting a radio communication die 280 on which a fourth redistribution layer structure 290 is formed on a transceiver die 230 as one step among steps of a manufacturing method of a second 3D integrated circuit structure 200.

Referring to FIG. 30, a radio communication die 280 having a fourth redistribution layer structure 290 formed on the transceiver die 230 is mounted using second connection members 271.

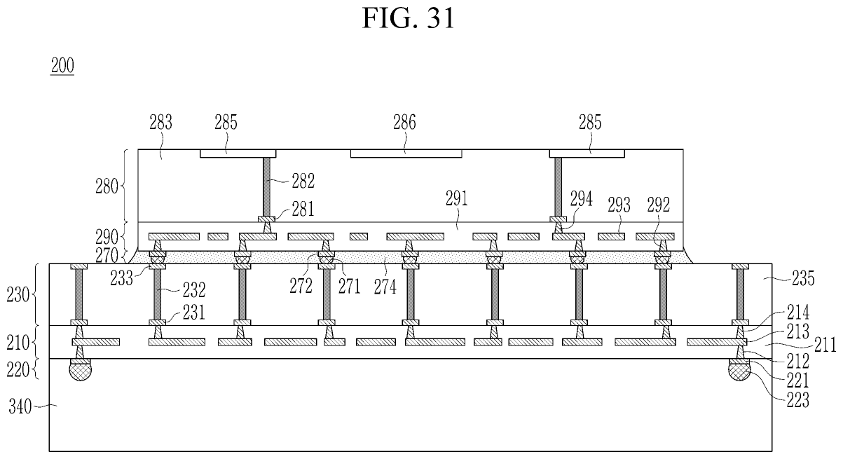

FIG. 31 is a cross-sectional view showing a step of forming an insulating member 274 between a transceiver die 230 and a fourth redistribution layer structure 290 as one step among steps of a manufacturing method of a second 3D integrated circuit structure 200.

Referring to FIG. 31, a second insulating member 274 is disposed between the transceiver die 230 and the fourth redistribution layer structure 290 to surround the second connection members 271 and the second connection pads 272. In this way, the stress between the transceiver die 230 and the fourth redistribution layer structure 290 may be relieved by disposing the second insulating member 274. In an embodiment, the second insulating member 274 may be formed of or include a molded under-fill (MUF) material.

In another embodiment, before mounting the radio communication die 280 on which the fourth redistribution layer structure 290 is formed on the transceiver die 230, a non-conductive film (NCF) as a second insulating member 274 may be attached on the transceiver die 230. A non-conductive film (NCF) has an adhesiveness and is attached on the transceiver die 230. The non-conductive film (NCF) has an uncured state that may be deformed by an external force. The non-conductive film (NCF) may be attached by heating at a temperature of about 170° C. to about 300° C. for about 1 second to about 20 seconds. Next, a radio communication die 280 on which a fourth redistribution layer structure 290 is formed is stacked on the non-conductive film (NCF). The second connection member 271 provided in the fourth redistribution layer structure 290 penetrates the non-conductive film (NCF) to contact the second upper connection pad 233 of the transceiver die 230.

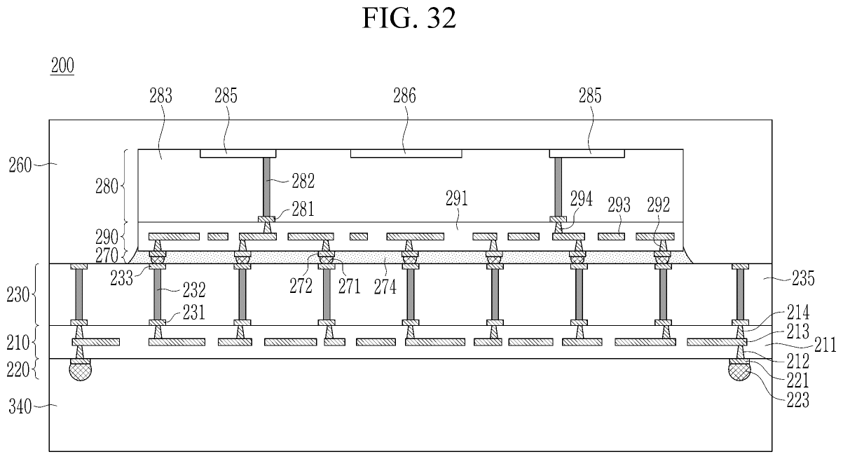

FIG. 32 is a cross-sectional view showing a step of covering a radio communication die 280 on which a fourth redistribution layer structure 290 is formed with a second molding material 260 on a transceiver die 230 as one step among steps of a manufacturing method of a second 3D integrated circuit structure 200.

Referring to FIG. 32, on the transceiver die 230, the radio communication die 280 on which the fourth redistribution layer structure 290 is formed is covered with the second molding material 260. As an embodiment, a molding process with the second molding material 260 may include a compression molding or a transfer molding process. In an embodiment, the second molding material 260 may be an epoxy molding compound (EMC). In another embodiment, the second molding material 260 may be formed of a thermosetting resin such as epoxy resin.

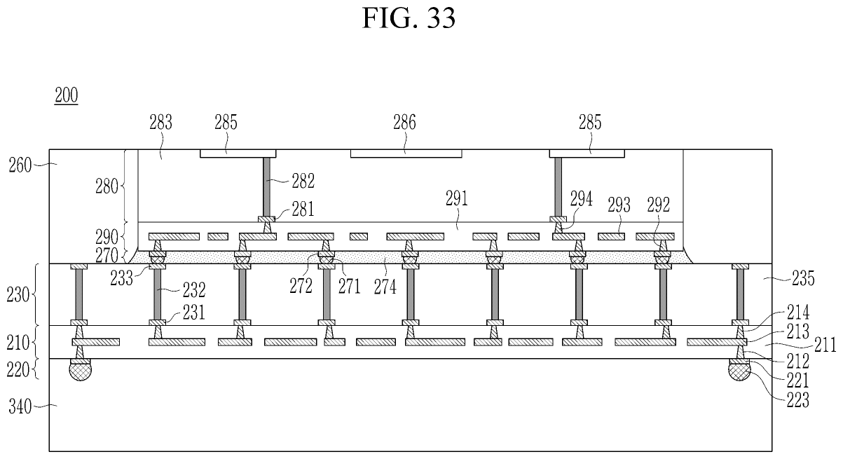

FIG. 33 is a cross-sectional view showing a step of planarizing a second molding material 260 as one step among steps of a manufacturing method of a second 3D integrated circuit structure 200.

Referring to FIG. 33, a chemical mechanical polishing (CMP) is performed to level the upper surface of the second molding material 260. A CMP process is applied to planarize the upper surface of the second molding material 260.

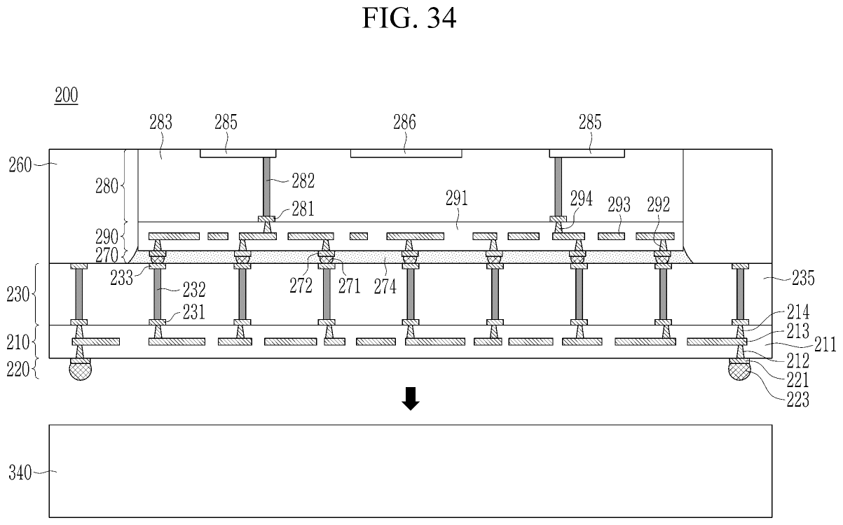

FIG. 34 is a cross-sectional view showing a step of de-bonding a third carrier 340 from a third redistribution layer structure 210 and a second external connection structure 220 as one step among steps of a manufacturing method of a second 3D integrated circuit structure 200.

Referring to FIG. 34, a third carrier 340 is removed from the third redistribution layer structure 210 and the second external connection structure 220.

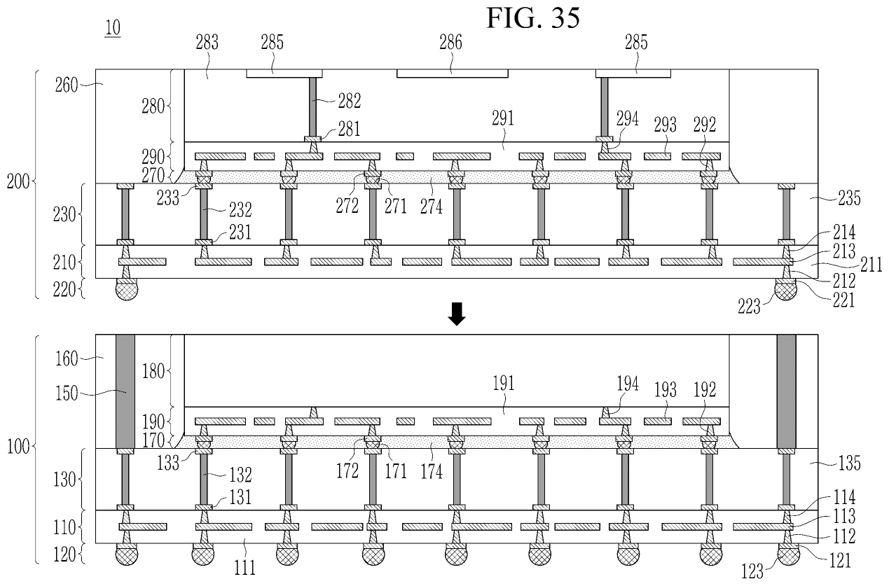

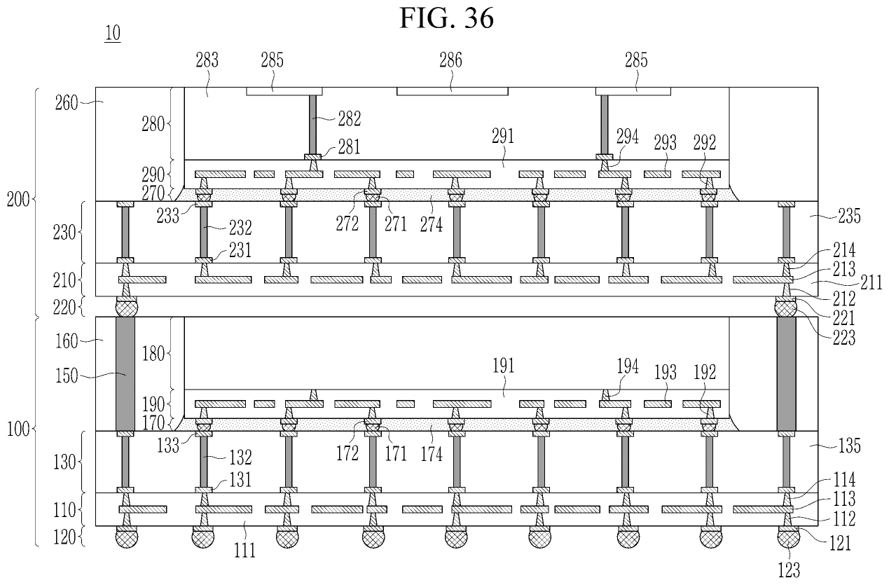

FIGS. 35 and 36 are cross-sectional views showing steps of combining a first 3D integrated circuit structure 100 with a second 3D integrated circuit structure 200 to form a semiconductor package 10.

FIG. 35 is a cross-sectional view showing a step of aligning a second 3D integrated circuit structure 200 on a first 3D integrated circuit structure 100 for a bonding as one step of steps of a manufacturing method of a semiconductor package 10.

Referring to FIG. 35, the second 3D integrated circuit structure 200 is aligned on the first 3D integrated circuit structure 100.

FIG. 36 is a cross-sectional view showing a step of bonding a second 3D integrated circuit structure 200 to a first 3D integrated circuit structure 100 as one step of steps of a manufacturing method of a semiconductor package 10.

Referring to FIG. 36, the second 3D integrated circuit structure 200 is bonded to the first 3D integrated circuit structure 100 by using second external connection members 223. After this, as shown in FIG. 1, a third insulating member 224 is disposed between the first 3D integrated circuit structure 100 and the second 3D integrated circuit structure 200 to surround the second external connection members 223 and the second conductive pads 221. The stress between the first 3D integrated circuit structure 100 and the second 3D integrated circuit structure 200 may be relieved by adding the third insulating member 224. In an embodiment, the third insulating member 224 may be formed of or include a molded under-fill (MUF) material.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the invention.

What is claimed is:

1. A semiconductor package comprising:
a first three-dimensional (3D) integrated circuit structure, the first 3D integrated circuit structure including a baseband die and a memory die on the baseband die; and
a second 3D integrated circuit structure on the first 3D integrated circuit structure, the second 3D integrated circuit structure including a transceiver die and a radio communication die on the transceiver die,
wherein one or more metal patterns are formed on an upper surface of the radio communication die.

2. The semiconductor package of claim 1, wherein:
the radio communication die includes a RF chip.

3. The semiconductor package of claim 1, wherein:
each metal pattern of the one or more metal patterns includes a PIFA antenna or a patch antenna.

4. The semiconductor package of claim 1, wherein the transceiver die includes:
a transmitter TX configured to generate a first radio frequency (RF) signal and transmit the generated first radio frequency (RF) signal; and
a receiver RX configured to receive a second radio frequency (RF) signal and process the received second radio frequency (RF) signal.

5. The semiconductor package of claim 1, wherein the first 3D integrated circuit structure includes:
a first redistribution layer structure on the lower surface of the baseband die; and
a second redistribution layer structure between the baseband die and the memory die.

6. The semiconductor package of claim 5, wherein:
the baseband die includes a plurality of first through silicon vias, and
the plurality of first through silicon vias electrically connects the memory die to the first redistribution layer structure.

7. The semiconductor package of claim 5, wherein:
the first 3D integrated circuit structure further includes a plurality of first connection members electrically connecting the second redistribution layer structure to the baseband die.

8. The semiconductor package of claim 7, wherein:
the first 3D integrated circuit structure further includes a first insulating member surrounding the plurality of first connection members.

9. The semiconductor package of claim 1, wherein the second 3D integrated circuit structure includes:
a third redistribution layer structure on the lower surface of the transceiver die; and
a fourth redistribution layer structure between the transceiver die and the radio communication die.

10. The semiconductor package of claim 9, wherein:
the transceiver die includes a plurality of second through silicon vias, and
the plurality of second through silicon vias electrically connects the radio communication die to the third redistribution layer structure.

11. The semiconductor package of claim 9, wherein:
the radio communication die includes a plurality of third through silicon vias, and
the plurality of third through silicon vias electrically connects the one or more metal patterns to the fourth redistribution layer structure.

12. The semiconductor package of claim 11, wherein:
the plurality of third through silicon vias includes a feeding line.

13. The semiconductor package of claim 9, wherein:
the second 3D integrated circuit structure further includes a plurality of second connection members electrically connecting the fourth redistribution layer structure to the transceiver die.

14. The semiconductor package of claim 13, wherein:
the second 3D integrated circuit structure further includes a second insulating member surrounding the plurality of second connection members.

15. A semiconductor package comprising:
a first three-dimensional (3D) integrated circuit structure; and
a second 3D integrated circuit structure on the first 3D integrated circuit structure,
wherein the first 3D integrated circuit structure includes:
a first redistribution layer structure;
a baseband die on the first redistribution layer structure;
a second redistribution layer structure on the baseband die;
a memory die on the second redistribution layer structure;
a plurality of conductive posts on the baseband die; and
a first molding material on the baseband die and covering the memory die, the second redistribution layer structure, and the plurality of conductive posts, and
the second three-dimensional integrated circuit structure includes:
a third redistribution layer structure;
a transceiver die on the third redistribution layer structure;
a fourth redistribution layer structure on the transceiver die;
a radio communication die on the fourth redistribution layer structure, the radio communication die including one or more antenna on the upper surface thereof;
a second molding material on the transceiver die and covering the radio communication die and the fourth redistribution layer structure; and
a plurality of connection members electrically connecting the third redistribution layer structure to the plurality of conductive posts.

16. The semiconductor package of claim 15, further comprising:
an insulating member surrounding the plurality of connection members.

17. The semiconductor package of claim 15, wherein:
the second molding material covers the side surface of the radio communication die, and an upper surface of the radio communication die is exposed to an outside.

18. A manufacturing method of a semiconductor package comprising:
manufacturing a first three-dimensional (3D) integrated circuit structure and a second 3D integrated circuit structure; and
mounting the second 3D integrated circuit structure on the first three-dimensional integrated circuit structure,
wherein the manufacturing of the first 3D integrated circuit structure includes:
forming a plurality of first through silicon vias on a first surface of a baseband die; and
mounting a memory die on a second surface of the baseband die opposite to the first surface,
the manufacturing of the second 3D integrated circuit structure includes:
forming a plurality of second through silicon vias on a first surface of a transceiver die; and
mounting a radio communication die on a second surface of the transceiver die opposite to the first surface, and
one or more metal patterns are formed on an upper surface of the radio communication die.

19. The manufacturing method of the semiconductor package of claim 18, wherein:
the manufacturing of the first 3D integrated circuit structure further includes covering the memory die with a molding material on the second surface of the baseband die after mounting the memory die on the second surface of the baseband die.

20. The manufacturing method of the semiconductor package of claim 19, wherein the manufacturing of the first 3D integrated circuit structure further includes, after covering the memory die on the second surface of the baseband die with a molding material, forming a plurality of conductive posts on the second surface of the baseband die.
